(19) United States
(12) Patent Application Publication
(10) Pub. No.: US 2025/0317664 A1
(43) Pub. Date: Oct. 9, 2025

(54) IMAGE SENSOR INCLUDING AUTO- FOCUS PIXELS

(71) Applicant: SAMSUNG ELECTRONICS CO., LTD., Suwon-si (KR)

(72) Inventors: Jiwon PARK, Suwon-si (KR); Jungbin Yun, Suwon-si (KR)

(73) Assignee: SAMSUNG ELECTRONICS CO., LTD., Suwon-si (KR)

(21) Appl. No.: 19/098,473

(22) Filed: Apr. 2, 2025

(30) Foreign Application Priority Data
Apr. 3, 2024 (KR) 10-2024-0045509

(51) Int. Cl. H04N 25/704; H04N 25/78; H10F 39/00

(52) U.S. Cl. CPC H04N 25/704; H04N 25/78; H10F 39/807

(57) ABSTRACT

An image sensor may include: a pixel array including: a first pixel group including: first pixels; a first auto-focus (AF) pixel; a second AF pixel; a first normal pixel; and a second normal pixel. The pixel array further includes a second pixel group including: second pixels; a third normal pixel; a fourth normal pixel; a fifth normal pixel; and a sixth normal pixel. The image sensor further includes: a row driver configured to provide a transmission control signal to the pixel array through transmission control lines including a first transmission control line, a second transmission control line, a third transmission control line, a fourth transmission control line, a fifth transmission control line, a sixth transmission control line, a seventh transmission control line, and an eighth transmission control line; and a readout circuit electrically connected to the first pixels and the second pixels.

### CROSS-REFERENCE TO RELATED APPLICATION

This application is based on and claims priority under 35 U.S.C. § 119 to Korean Patent Application No. 10-2024-0045509, filed on Apr. 3, 2024, in the Korean Intellectual Property Office, the disclosure of which is incorporated by reference herein in its entirety.

### BACKGROUND

The disclosure relates to an image sensor, and more particularly, to an image sensor including auto-focus (AF) pixels.

Image sensors, which capture images and convert the images into electrical signals, are used not only in consumer electronic devices, such as digital cameras, mobile phone cameras, and portable camcorders, but also in cameras mounted on automobiles, security devices, and robots. The image sensors each include a pixel array, and each pixel included in the pixel array may include a photodiode. The image sensor is required to perform an AF function so that image capture may be performed quickly and accurately. Generally, AF pixels are arranged to correspond to different color filters to calculate phase difference when performing the AF function. However, when the AF pixels have deep trench isolation-center-cut (DCC) structures, when AF pixels (Left (L), Right (R)) are arranged to correspond to different color filters, phase signals are mixed in a 4-SUM mode (or binning mode), making it impossible to perform the AF function.

### SUMMARY

Embodiments of the disclosure provide an image sensor that performs an auto-focus (AF) function based on pixels having deep trench isolation-center-cut (DCC) structures.

The problems to be solved by the technical idea of the disclosure are not limited to the above-mentioned problems, and other problems not mentioned will be clearly understood by those skilled in the art from the following description.

According to one or more example embodiments, an image sensor may include: a pixel array including: a first pixel group including: first pixels disposed in first rows and first columns; a first auto-focus (AF) pixel; a second AF pixel; a first normal pixel; and a second normal pixel. The pixel array further includes a second pixel group including: second pixels disposed in second rows and second columns; a third normal pixel; a fourth normal pixel; a fifth normal pixel; and a sixth normal pixel. The image sensor may further include: a row driver configured to provide a transmission control signal to the pixel array through transmission control lines, the transmission control lines may include a first transmission control line, a second transmission control line, a third transmission control line, a fourth transmission control line, a fifth transmission control line, a sixth transmission control line, a seventh transmission control line, and an eighth transmission control line; and a readout circuit electrically connected to the first pixels and the second pixels. The first pixels may be connected to the row driver through any one of the first transmission control line, the second transmission control line, the third transmission control line, and the fourth transmission control line, and the second pixels may be connected to the row driver through the fifth transmission control line, the sixth transmission control line, the seventh transmission control line, and the eighth transmission control line.

According to one or more example embodiments, an image sensor may include: a pixel array including: a first pixel group including: first pixels disposed in first rows and first columns; a first auto-focus (AF) pixel; a second AF pixel; a first normal pixel; and a second normal pixel. The pixel array further includes: a second pixel group including: second pixels disposed in second rows and second columns; a third normal pixel; a fourth normal pixel; a fifth normal pixel; and a sixth normal pixel. The image sensor may further include: a row driver configured to provide a transmission control signal to the pixel array through transmission control lines, the transmission control lines may include a first transmission control line, a second transmission control line, a third transmission control line, a fourth transmission control line, and a fifth transmission control line; and a readout circuit electrically connected to the first pixels and the second pixels. Remaining pixels excluding a target AF pixel among the first pixels and the second pixels may be connected to the row driver through any one of the first transmission control line, the second transmission control line, the third transmission control line, and the fourth transmission control line. The target AF pixel may be either the first AF pixel or the second AF pixel and is connected to the row driver through the fifth transmission control line.

According to one or more example embodiments, an image sensor may include: a pixel array may including: a first pixel group including: first pixels disposed in first rows and first columns; a first auto-focus (AF) pixel; a second AF pixel; a third AF pixel; and a fourth AF pixel. The pixel array may further include: a second pixel group including: second pixels disposed in second rows and second columns; a first normal pixel; a second normal pixel; a third normal pixel; and a fourth normal pixel. The image sensor may further include: a row driver configured to provide a transmission control signal to the pixel array through transmission control lines, the transmission control lines may include a first transmission control line, a second transmission control line, a third transmission control line, a fourth transmission control line, a fifth transmission control line, and a sixth transmission control line; and a readout circuit electrically connected to the first pixels and the second pixels. The first AF pixel and the first normal pixel may be connected to the first transmission control line. The second normal pixel may be connected to the second transmission control line. The third AF pixel and the third normal pixel of may be connected to the third transmission control line. The fourth normal pixel may be connected to the fourth transmission control line. The second AF pixel may be connected to the row driver through the fifth transmission control line. The fourth AF pixel may be connected to the row driver through the sixth transmission control line.

### BRIEF DESCRIPTION OF DRAWINGS

Embodiments will be more clearly understood from the following detailed description taken in conjunction with the accompanying drawings in which:

FIG. 1 is a diagram illustrating a structure of a digital imaging device according to one or more embodiments;

FIG. 2 illustrates an example of a pixel array 110 in FIG. 1, according to one or more embodiments;

FIG. 3A is a diagram illustrating a pixel array of an image sensor according to one or more embodiments;

FIG. 3B is a cross-sectional view of a portion of a pixel array taken along line A-A′ in FIG. 3A, according to one or more embodiments;

FIG. 4 is a circuit diagram illustrating an example of a first pixel group in the pixel array of FIG. 3A, according to one or more embodiments;

FIG. 5 is a diagram illustrating a pixel array of an image sensor according to one or more embodiments;

FIG. 6A is a timing diagram illustrating transmission control signals provided to a first pixel group and a second pixel group in FIG. 5, according to one or more embodiments;

FIG. 6B is a timing diagram illustrating transmission control signals provided to a first pixel group and a second pixel group in FIG. 5, according to one or more embodiments;

FIG. 7 is a diagram illustrating a pixel array of an image sensor according to one or more embodiments;

FIG. 8A is a timing diagram illustrating transmission control signals provided to a first pixel group and a second pixel group in FIG. 7, according to one or more embodiments;

FIG. 8B is a timing diagram illustrating transmission control signals provided to a first pixel group and a second pixel group in FIG. 7, according to one or more embodiments;

FIG. 9 is a diagram illustrating a pixel array of an image sensor according to one or more embodiments;

FIG. 10A is a timing diagram illustrating transmission control signals provided to a first pixel group and a second pixel group in FIG. 9, according to one or more embodiments;

FIG. 10B is a timing diagram illustrating transmission control signals provided to a first pixel group and a second pixel group in FIG. 9, according to one or more embodiments;

FIG. 11 is a block diagram of an electronic device including a multi-camera module according to one or more embodiments; and

FIG. 12 is a detailed block diagram of the camera module of FIG. 11 according to one or more embodiments.

### DETAILED DESCRIPTION

Hereinafter, embodiments of the disclosure will be described in detail with reference to the attached drawings. Embodiments of the disclosure are illustrated in the drawings and related detailed descriptions are described, but this is not intended to limit various embodiments of the disclosure to a particular form. For example, it is obvious to those skilled in the art that the embodiments of the disclosure may be changed in various ways.

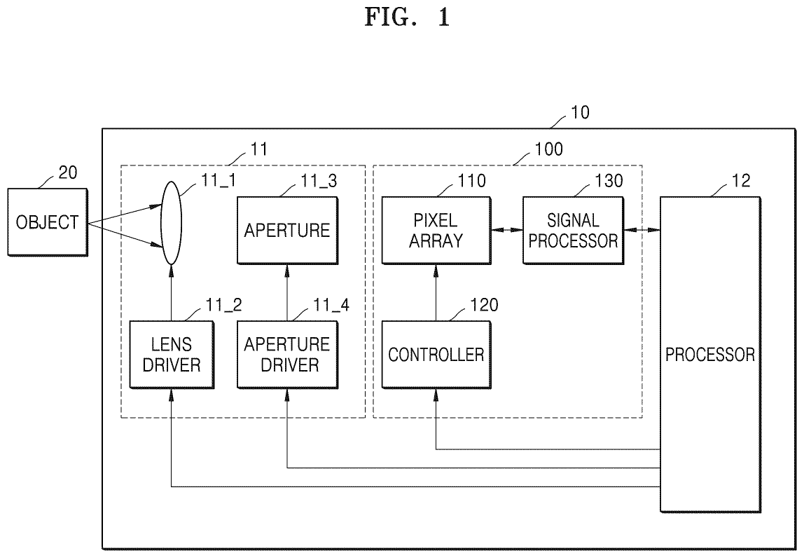

FIG. 1 is a diagram illustrating a structure of a digital imaging device 10 according to one or more embodiments, and is a diagram for explaining how the digital imaging device 10 performs an auto-focus (AF) function.

The digital imaging device 10 according to one or more embodiments may include an imaging portion 11, an image sensor 100, and a processor 12. The digital imaging device 10 may have a focus detection function.

All operations of the digital imaging device 10 may be controlled by the processor 12. The processor 12 may provide control signals for the operation of each component to a lens driver 11_2, an aperture driver 11_4, a controller 120, and the like.

The imaging portion 11 is a component that receives light and may include a lens 11_1, the lens driver 11_2, an aperture 11_3, and the aperture driver 11_4. The lens 11_1 may include a plurality of lenses.

The lens driver 11_2 may communicate information about focus detection with the processor 12 and may adjust the position of the lens 11_1 according to a control signal provided from the processor 12. The lens driver 11_2 may move the lens 11_1 in a direction in which the distance from an object 20 increases or decreases. Accordingly, the distance between the lens 11_1 and the object 20 may be adjusted. Depending on the position of the lens 11_1, the object 20 may be in focus or out of focus.

For example, when the distance between the lens 11_1 and the object 20 is relatively short, the lens 11_1 may be out of the in-focus position for focusing on the object 20 and a phase difference may occur between images captured by the image sensor 100. The lens driver 11_2 may move the lens 11_1 in a direction in which the distance from the object 20 increases, based on a control signal provided from the processor 12.

Alternatively, when the distance between the lens 11_1 and the object 20 is relatively long, the lens 11_1 may be out of the in-focus position and a phase difference may occur between images formed on the image sensor 100. The lens driver 11_2 may move the lens 11_1 in a direction in which the distance from the object 20 decreases, based on a control signal provided from the processor 12.

The image sensor 100 may convert incident light into an image signal. The image sensor 100 may include a pixel array 110, the controller 120, and a signal processor 130. An optical signal passing through the lens 11_1 and the aperture 11_3 may reach a light-receiving surface of the pixel array 110 and form an image of the subject.

The pixel array 110 may be a complementary metal oxide semiconductor image sensor (CIS) that converts optical signals into electrical signals. The sensitivity of the pixel array 110 may be adjusted by the controller 120. The pixel array 110 may include a plurality of pixels that convert optical signals into electrical signals. Each of the plurality of pixels may generate a pixel signal according to the intensity of sensed light.

The image sensor 100 may provide image information to the processor 12, and the processor 12 may perform a phase difference operation by using the image information. For example, the processor 12 may receive, from the signal processor 130, image information according to a pixel signal generated by an AF pixel and perform phase difference calculation, and the phase difference calculation may be obtained by performing a correlation operation of the image information. The processor 12 may obtain the position of focus, the direction of focus, or the distance between the object 20 and the image sensor 100 as a result of the phase difference calculation. The processor 12 may output a control signal to the lens driver 11_2 to move the position of the lens 11_1, based on the result of the phase difference calculation.

The processor 12 may reduce noise for the input signal and perform image signal processing to improve picture quality, such as gamma correction, color filter array interpolation, color matrix, color correction, and color enhancement. In addition, image data generated by performing the image signal processing to improve image quality may be compressed to generate an image file, or image data may be restored from the image file.

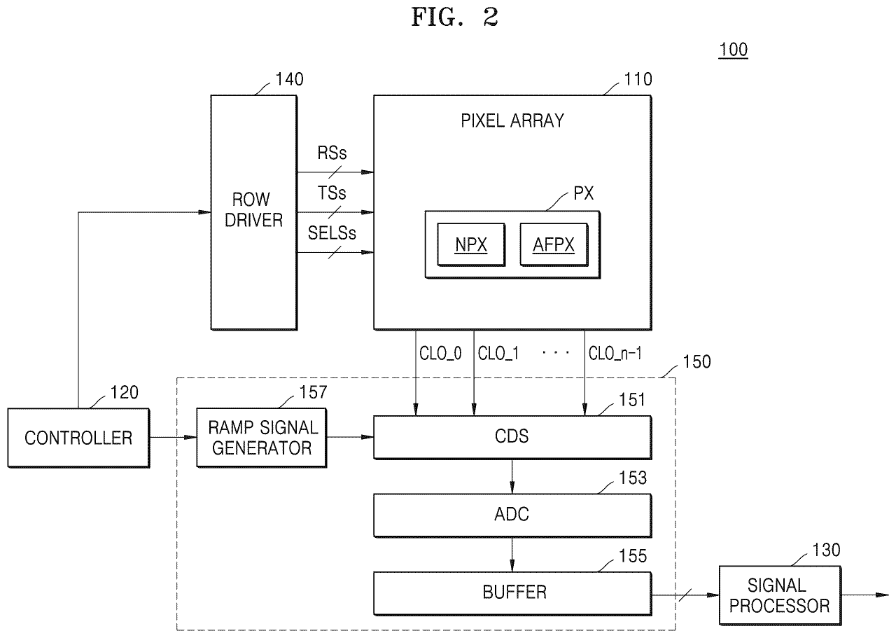

FIG. 2 illustrates an example of the pixel array 110 in FIG. 1, according to one or more embodiments.

Referring to FIG. 2, the image sensor 100 may include a pixel array 110, a controller 120, a signal processor 130, a row driver 140, and a signal read portion 150. The signal read portion 150 may include a correlated-double sampler (CDS) 151, an analog-digital converter (ADC) 153, and a buffer 155.

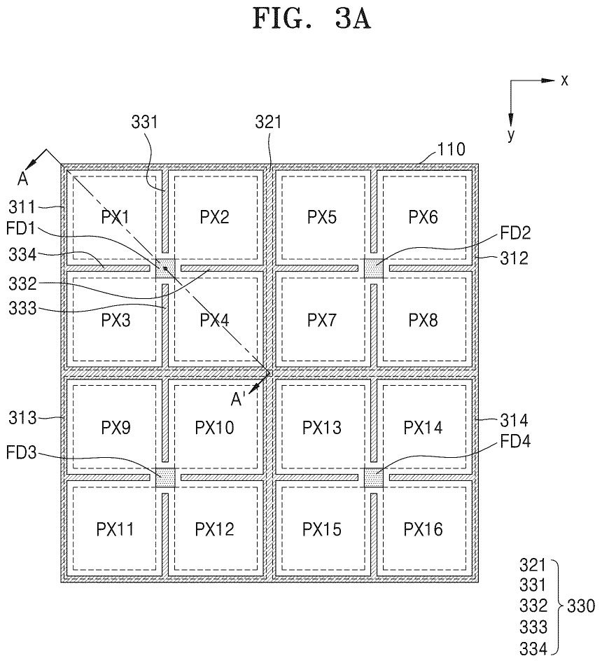

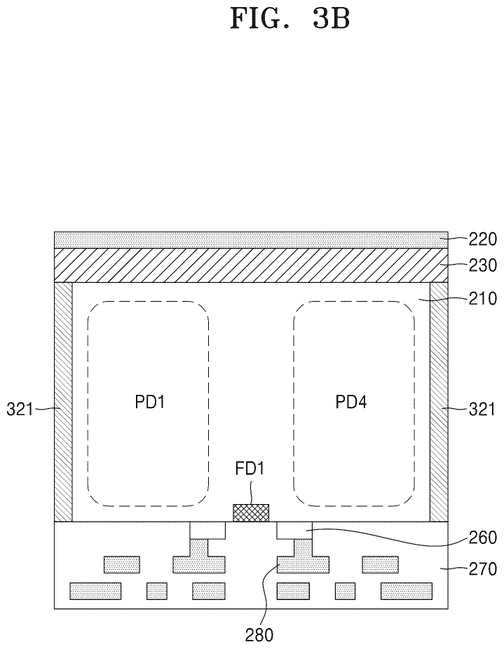

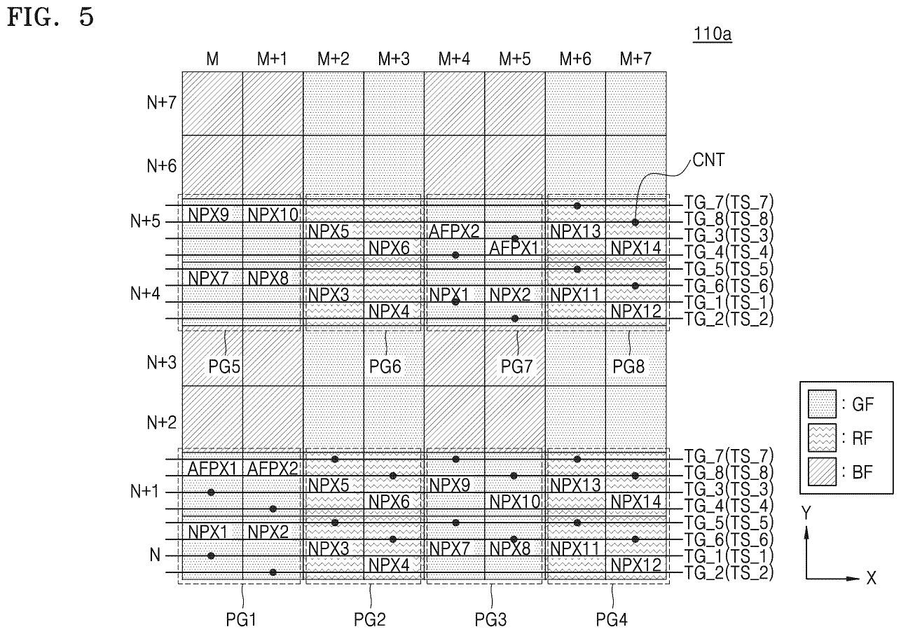

The pixel array 110 may include a plurality of pixels PX that convert optical signals into electrical signals. Each of the plurality of pixels PX may generate a pixel signal according to the intensity of detected light. The plurality of pixels PX may include a plurality of normal pixels NPX for performing an image capturing function, and a plurality of AF pixels AFPX for performing an AF function or a distance measurement function. The plurality of AF pixels AFPX may generate pixel signals for image capturing when not performing the AF function. For example, the plurality of pixels PX may include a first pixel group including AF pixels AFPX and normal pixels NPX, and a second pixel group including normal pixels NPX (See FIGS. 5, 7, and 9). In this case, the AF pixels AFPX of the first pixel group may include a first photodiode and a second photodiode arranged adjacent to each other in a first direction (e.g., the X direction in FIG. 3). The first photodiode may correspond to a first AF pixel, and the second photodiode arranged adjacent to the first photodiode in the first direction may correspond to a second AF pixel. One micro lens may be disposed on the first photodiode and the second photodiode.

The pixel array 110 according to one or more embodiments may include a device isolation pattern that electrically separates pixel groups from each other. In this case, the device isolation pattern may include a plurality of parts that electrically separate pixels included in each of the pixel groups from each other, and each of the plurality of parts may be formed to be spaced apart from a floating diffusion node positioned at the center of each of the pixel groups (e.g., a deep trench isolation-center-cut (DCC) structure). For example, the pixel array 110 may further include a device isolation pattern that electrically separates the first pixel group from the second pixel group. In this case, the device isolation pattern may include a plurality of parts that are formed between pixels included in each of the first pixel group and the second pixel group and electrically separate the pixels included in each of the first pixel group and the second pixel group from each other. Each of the plurality of parts may be formed to be spaced apart from a floating diffusion node positioned at the center of each of the first pixel group and the second pixel group, and the floating diffusion node may be electrically connected to the pixels included in each of the first pixel group and the second pixel group.

Each of the normal pixels NPX and the AF pixels AFPX may output a pixel signal to the CDS 151 through a corresponding one of first to n-th column output lines CLO_0 to CLO_n-1. In an AF mode, pixel signals output from the AF pixels AFPX may be phase signals used to calculate the phase difference. The phase signals may include information about the positions of images formed on the image sensor 100, and the focus position of a lens (e.g., the lens 11_1 in FIG. 1) may be calculated based on calculated phase differences. For example, the position of the lens 11_1 that makes the phase difference 0 may be the focus position.

The phase signals may be used not only for focusing on an object but also for measuring the distance between an object (e.g., the object 20 in FIG. 1) and the image sensor 100. To measure the distance between the object 20 and the image sensor 100, additional information, such as the phase differences between images formed on the image sensor 100, the distance between the lens 11_1 and the image sensor 100, the size of the lens 11_1, and the focus position of the lens 11_1, may be referenced.

The controller 120 may control the row driver 140 to cause the pixel array 110 to absorb light and accumulate charge, temporarily store the accumulated charge, and output an electrical signal according to the stored charge to the outside of the pixel array 110. In addition, the controller 120 may control the signal read portion 150 to measure the level of a pixel signal provided by the pixel array 110.

The row driver 140 may generate signals (i.e., reset control signals RSs, transmission control signals TSs, and selection signals SELSs) for controlling the pixel array 110 and provide the signals to the plurality of pixels PX through a plurality of transmission control lines. The row driver 140 may determine the activation and deactivation timing of the reset control signals RSs, the transmission control signals TSs, and the selection signals SELSs, which are provided to the plurality of pixels PX to perform an AF function or an image capturing function.

In one or more embodiments, the pixel array 110 may receive a transmission control signal TS from the row driver 140 through a plurality of transmission control lines, and may include a plurality of pixel groups each connected to different column output lines among the first to n-th column output lines CLO_0 to CLO_n−1. Therefore, the image sensor 100 according to one or more embodiments may provide an AF function at high speed by using phase signals output from the plurality of pixel groups.

The CDS 151 may sample and hold the pixel signal provided by the pixel array 110. The CDS 151 may double sample the level of a certain noise and the level according to the pixel signal and output a level corresponding to the difference therebetween. In addition, the CDS 151 may receive a ramp signal generated by a ramp signal generator 157, compare the ramp signal to the pixel signal, and output a comparison result. The ADC 153 may convert an analog signal corresponding to the level received from the CDS 151 into a digital signal. The buffer 155 may latch a digital signal, and the latched signal may be sequentially output to the signal processor 130 or the outside of the image sensor 100.

The signal processor 130 may perform signal processing based on pixel signals output from the plurality of pixels PX. For example, the signal processor 130 may perform noise reduction processing, gain adjustment, waveform normalization processing, interpolation processing, white balance processing, gamma processing, edge emphasis processing, etc. In addition, the signal processor 130 may perform signal processing based on phase signals output from the plurality of pixels PX during the AF operation, and may output signal-processed information to the processor 12 so that the processor 12 performs phase difference calculation for AF operation. In one or more embodiments, the signal processor 130 may be provided in a processor (e.g., the processor 12 in FIG. 1) external to the image sensor 100.

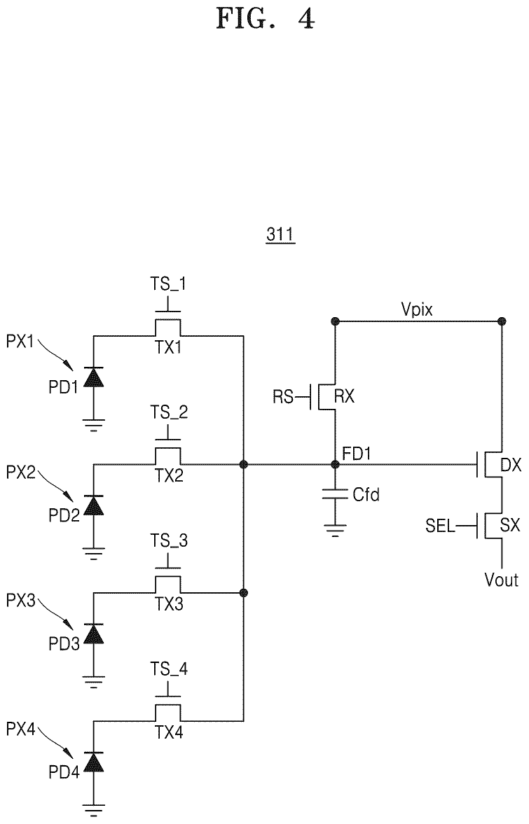

According to the image sensor 100 according to various embodiments, the AF function may be performed at high speed even in pixels (see FIGS. 3A to 4) having a DCC structure through various arrangements of control lines (e.g., control lines that transmit transmission control signals) connected to the row driver 140.

In addition, various embodiments of the disclosure may reduce the probability of defects occurring during the product production process through layout margins secured by arranging control lines in various ways.

FIG. 3A is a diagram illustrating a pixel array of an image sensor according to one or more embodiments.

Referring to FIGS. 3A and 3B, the pixel array 110 according to one or more embodiments may include a plurality of pixels PX1 to PX16 and a device isolation pattern 330 that electrically separates the plurality of pixels from each other. In this case, it may be understood that each of the plurality of pixels PX1 to PX16 corresponds to either the AF pixel AFPX or the normal pixel NPX in FIG. 2. For example, the first pixel PX1 may be a first AF pixel, the second pixel PX2 may be a second AF pixel, the third pixel PX3 may be a first normal pixel, and the fourth pixel PX4 may be a second normal pixel. For another example, the first pixel PX1 to the fourth pixel PX4 may be first to fourth normal pixels. For another example, the first pixel PX1 to the fourth pixel PX4 may be first to fourth AF pixels.

Referring to FIG. 3A, the pixel array 110 may include a first pixel group 311, a second pixel group 312, a third pixel group 313, and a fourth pixel group 314, each including pixels arranged in 2×2.

For example, the pixel array 110 may include the first pixel group 311 including first to fourth pixels PX1 to PX4 arranged in 2×2. In addition, the pixel array 110 may include the second pixel group 312 including fifth to eighth pixels PX5 to PX8 arranged in 2×2. In addition, the pixel array 110 may include the third pixel group 313 including ninth to twelfth pixels PX9 to PX12 arranged in 2X2. In addition, the pixel array 110 may include the fourth pixel group 314 including thirteenth to sixteenth pixels PX13 to PX16 arranged in 2×2.

The first to fourth pixel groups 311 to 314 may be arranged in a 2×2 arrangement to form the pixel array 110. Therefore, for example, the pixel array 110 may include 16 pixels arranged in 4×4, but is not limited thereto.

Referring to FIGS. 2 and 3A, the image sensor 100 according to one or more embodiments may include a plurality of microlenses formed to correspond to at least one pixel among the plurality of pixels PX1 to PX16. For example, the first pixel group 311 of the image sensor 100 may include at least one microlens among a first microlens formed to correspond to the first pixel PX1 and the second pixel PX2 and a second microlens formed to correspond to the third pixel PX3 and the fourth pixel PX4. However, the configuration of microlenses formed to correspond to at least one pixel is not limited to the aforementioned example.

The pixel array 110 may include a device isolation pattern 330 that electrically separates the plurality of pixels PX1 to PX16 from each other.

More specifically, the device isolation pattern 330 may include a first isolation pattern 321 that electrically separates the first to fourth pixel groups 311 to 314 from each other.

According to one or more embodiments, the device isolation pattern 330 may include a plurality of parts 331, 332, 333, and 334 extending from the first isolation pattern 321 and electrically separating a plurality of pixels from each other. The device isolation pattern 330 may include the plurality of parts 331, 332, 333, and 334 that are formed between pixels included in the first pixel group 311 and electrically separate the first to fourth pixels PX1 to PX4 from each other.

In this case, the plurality of parts 331, 332, 333, and 334 may include a first part 331 extending in a second direction (e.g., +y direction) between the first pixel PX1 and the second pixel PX2. The first pixel PX1 and the second pixel PX2 may be electrically separated from each other by the first part 331.

In addition, the plurality of parts 331, 332, 333, and 334 may include a second part 332 extending in a direction (e.g., −x direction) opposite to a first direction between the second pixel PX2 and the fourth pixel PX4. The second pixel PX2 and the fourth pixel PX4 may be electrically separated from each other by the second part 332.

In addition, the plurality of parts 331, 332, 333, and 334 may include a third part 333 extending in a direction (e.g., −y direction) opposite to the second direction between the third pixel PX3 and the fourth pixel PX4. The third pixel PX3 and the fourth pixel PX4 may be electrically separated from each other by the third part 333.

In addition, the plurality of parts 331, 332, 333, and 334 may include a fourth part 334 extending in the first direction (e.g., +x direction) between the third pixel PX3 and the first pixel PX1. The third pixel PX3 and the first pixel PX1 may be electrically separated from each other by the fourth part 334.

According to one or more embodiments, the first part 331, the second part 332, the third part 333, and the fourth part 334 may be each spaced apart from the center C of the first pixel group 311.

For example, one end of each of the first part 331, the second part 332, the third part 333, and the fourth part 334 may be connected to the first isolation pattern 321, and the other end may be spaced apart from the center C of the first pixel group 311.

For another example, the plurality of parts 331, 332, 333, and 334 may each be spaced apart from the first isolation pattern 321 and the center C of the first pixel group 311. For another example, one end of each of the first part 331, the second part 332, the third part 333, and the fourth part 334 may be connected to the first isolation pattern 321, the other end of the first part 331 and the other end of the third part 333 may be connected to each other, and the other end of the second part 332 and the other end of the fourth part 334 may be connected to each other.

In this case, for example, the device isolation pattern 330 may be formed through a deep trench isolation (DTI) process, but is not limited thereto.

In addition, for example, the device isolation pattern 330 may include oxide and/or polysilicon.

The pixel array 110 may include floating diffusion nodes FD1, FD2, FD3, and FD4 that are electrically connected to a plurality of pixels.

More specifically, the pixel array 110 may include a first floating diffusion node FD1 to a fourth floating diffusion node FD4, which are electrically connected to pixels included in each of the pixel groups 311, 312, 313, and 314.

For example, the pixel array 110 may include the first floating diffusion node FD1 electrically connected to the first to fourth pixels PX1 to PX4 included in the first pixel group 311. In addition, the pixel array 110 may include the second floating diffusion node FD2 electrically connected to the fifth to eighth pixels PX5 to PX8 included in the second pixel group 312. In addition, the pixel array 110 may include the third floating diffusion node FD3 electrically connected to the ninth to twelfth pixels PX9 to PX12 included in the third pixel group 313. In addition, the pixel array 110 may include the fourth floating diffusion node FD4 electrically connected to the thirteenth to sixteenth pixels PX13 to PX16 included in the fourth pixel group 314.

According to one or more embodiments, the first to fourth floating diffusion nodes FD1 to FD4 may be formed at positions corresponding to the centers of the pixel groups, respectively. For example, the first floating diffusion node FD1 may be formed at a position corresponding to the center C of the first pixel group 311. However, the positions where the floating diffusion nodes are formed are not limited to the aforementioned example and may be formed at various positions that may be electrically connected to a plurality of pixels.

According to one or more embodiments, the first part 331, the second part 332, the third part 333, and the fourth part 334 may each be spaced apart from the first floating diffusion node FD1 to the fourth floating diffusion node.

In addition, the device isolation pattern 330 may extend into each of the second pixel group 312, the third pixel group 313, and the fourth pixel group 314 and may further include a plurality of parts formed to be spaced apart from the center of each of the second to fourth pixel groups 312, 313, and 314.

In this case, a plurality of parts extending toward the center of each of the second to fourth pixel groups 312, 313, and 314 may also be spaced apart from the second to fourth floating diffusion nodes FD2 to FD4, respectively.

Accordingly, the pixel array 110 according to one or more embodiments may reduce the area for forming a floating diffusion node for each of the plurality of pixels. In addition, the pixel array 110 may reduce wiring and structures for connecting a plurality of pixels to floating diffusion nodes.

FIG. 3B is a cross-sectional view of a portion of the pixel array 110 taken along line A-A′ in FIG. 3A, according to one or more embodiments.

Referring to FIG. 3B, the pixel array 110 according to one or more embodiments may include a substrate 210, a color filter 230, a light transmitting layer 220, and an insulating layer 270. In this case, the substrate 210 may include photodiodes PD1 and PD4 respectively corresponding to a plurality of pixels, that is, the first and fourth pixels PX1 and PX4. For example, the first pixel PX1 may be an AF pixel and the fourth pixel PX4 may be a normal pixel, and for another example, both the first pixel PX1 and the fourth pixel PX4 may be AF pixels. However, the arrangement of the pixel array according to one or more embodiments is not limited thereto.

According to one or more embodiments, the color filter 230 and the light transmitting layer 220 may be sequentially disposed on one surface of the substrate 210. For example, the color filter 230 in an area corresponding to the first pixel group 311 may be a green color filter, but is not limited thereto.

The photodiodes PD1 and PD4 may obtain light that has passed through a microlens, the light transmitting layer 220, and the color filter 230.

The insulating layer 270 may be disposed under the photodiodes PD1 and PD4 or the substrate 210. For example, the insulating layer 270 may include a plurality of elements 260 and wiring patterns 280 connected to the plurality of elements 260. The plurality of elements 260 and the wiring patterns 280 included in the insulating layer 270 may operate to obtain a pixel signal from the plurality of pixels PX1 and PX4. The pixel signal obtained from the plurality of pixels PX1 and PX4 may include a phase signal or a color signal.

According to one or more embodiments, the first photodiode PD1 corresponding to the first pixel PX1 and the fourth photodiode PD4 corresponding to the fourth pixel PX4 may share the first floating diffusion node FD1.

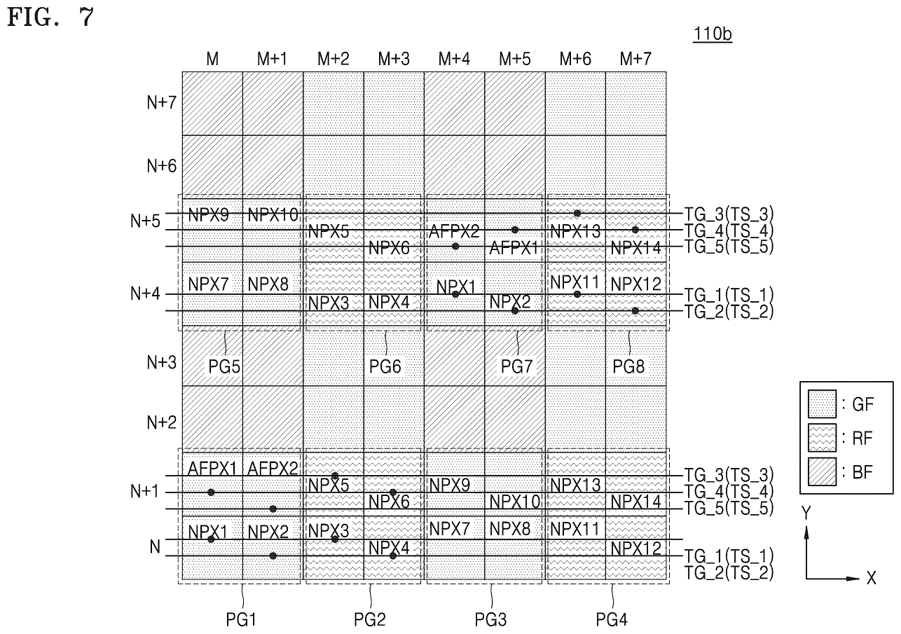

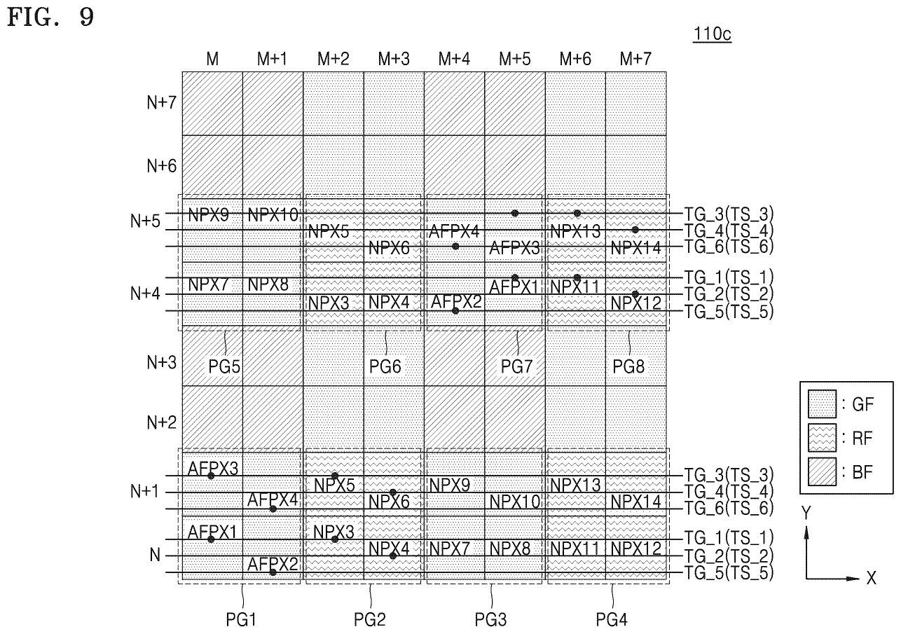

Each of the plurality of elements 260 adjacent to the first floating diffusion node FD1 may be referred to as a transfer transistor. In this case, the gate of the transfer transistor may have a vertical structure in which at least a portion of the gate is buried in the substrate 210. Each transfer transistor is connected to the row driver 140 (see FIG. 2) through a plurality of transmission control lines (e.g., a first transmission control line TG_1 to an eighth transmission control line TG_8 in FIG. 5, a first transmission control line TG_1 to a fifth transmission control line TG_5 in FIG. 7, and a first transmission control line TG_1 to a sixth transmission control line TG_6 in FIG. 9).

The plurality of pixels PX1, PX2, PX3, and PX4 included in the first pixel group 311 may be electrically separated, by the first isolation pattern 321, from the plurality of pixels PX5, PX6, PX7, and PX8 included in the second pixel group 312. The device isolation pattern 330 (or first isolation pattern 321) may be separated to the extent that charge overflow does not occur between adjacent photodiodes.

FIG. 4 is a circuit diagram illustrating an example of a first pixel group in the pixel array of FIG. 3A, according to one or more embodiments.

Referring to FIGS. 3A, 3B, and 4, according to one or more embodiments, the first pixel group 311 may include first to fourth pixels PX1 to PX4 that share the first floating diffusion node FD1. In this case, the first pixel PX1 and the third pixel PX3 may be located on the left L from the center C, and the second pixel PX2 and the fourth pixel PX4 may be located on the right from the center C.

The charge generated through each of the first to fourth photodiodes PD1 to PD4 may be transferred to the first floating diffusion node FD1 through a first transfer transistor TX1 to a fourth transfer transistor TX4.

In this case, the charges generated through the first to fourth photodiodes PD1 to PD4 may be sequentially transferred to the first floating diffusion node FD1 according to transmission control signals TS_1, TS_2, TS_3, and TS_4 transmitted from the row driver 140 to the first to fourth transfer transistors TX1 to TX4. For example, the transmission control signals TS_1, TS_2, TS_3, and TS_4 may be transmitted from the row driver 140 to the first to fourth transfer transistors TX1 to TX4 through transmission control lines connecting a row driver to the first to fourth transfer transistors TX1 to TX4.

For example, the charge generated through the first photodiode PD1 may be transferred to the first floating diffusion node FD1 according to the first transmission control signal TS_1 transmitted to the first transfer transistor TX1 through a first transmission control line.

In addition, the charge accumulated in the first floating diffusion node FD1 may be transferred to a driving transistor DX and output as an output voltage Vout through a selection transistor SX.

Subsequently, the charge stored in the first floating diffusion node FD1 may be reset in response to a reset signal RS transmitted from the row driver 140 to a reset transistor RX.

Subsequently, the charge generated through the second photodiode PD2 may be transferred to the first floating diffusion node FD1 according to the second transmission signal TS_2 transmitted to the second transfer transistor TX2.

Accordingly, the image sensor 100 according to one or more embodiments may reduce the cost and area consumed to implement a floating diffusion node for each pixel, secure a layout margin through the arrangement of various transmission control lines, and perform a high-speed AF function.

According to one or more embodiments, a description of an image sensor that performs an AF function based on various arrangements of transmission control lines in a pixel array will be given in detail with reference to FIGS. 5 to 10B below.

FIG. 5 is a diagram illustrating a pixel array 110a of an image sensor according to one or more embodiments.

In the drawings (e.g., FIGS. 5, 7, and 9), the connection relationship between pixels and transmission control lines (e.g., the first transmission control line TG_1 to the eighth transmission control line TG_8) providing transmission control signals to the pixels are indicated through contacts CNT. In the drawings, a contact CNT disposed on a certain photodiode may mean that a transmission control signal (e.g., the first transmission control signal TS_1 to the eighth transmission control signal TS_8) provided through a transmission control line connected to the contact CNT is input to the gate of a transfer transistor connected to the certain photodiode. Transmission control signals described with reference to the drawings may be included in the transmission control signals TSs in FIG. 2. In addition, the case where, in the drawings, pixels are connected to the same transmission control line may include one or more embodiments in which the pixels are connected to the same transmission control line, and one or more embodiments in which the pixels are connected to different transmission control lines but receive the same transmission control signal.

In FIG. 5, the pixel array 110a may include a plurality of pixel groups arranged in a plurality of rows (e.g., N-th row to (N+7)-th row) and a plurality of columns (e.g., M-th column to (M+7)-th column).

Referring to FIG. 5, the pixel array 110a may include a plurality of pixel groups, for example, first to eighth pixel groups PG1 to PG8. The first pixel group PG1 and the second pixel group PG2 may be arranged side by side in a first direction X, the third pixel group PG3 and the fourth pixel group PG4 may be arranged side by side in the first direction X, the fifth pixel group PG5 and the sixth pixel group PG6 may be arranged side by side in the first direction X, and the seventh pixel group PG7 and the eighth pixel group PG8 may be arranged side by side in the first direction X. The first pixel group PG1 and the third pixel group PG3 may be arranged in a second direction Y with two rows (e.g., N+2 and N+3 rows) therebetween, the second pixel group PG2 and the sixth pixel group PG6 may be arranged in the second direction Y with two rows (e.g., the (N+2) and (N+3) rows) therebetween, the third pixel group PG3 and the seventh pixel group PG7 may be arranged in the second direction Y with two rows (e.g., the (N+2) and (N+3) rows) therebetween, and the fourth pixel group PG4 and the eighth pixel group PG8 may be arranged in the second direction Y with two rows (e.g., the (N+2) and (N+3) rows) therebetween.

Each of the first to eighth pixel groups PG1 to PG8 may include four pixels arranged in two rows and two columns. In one or more embodiments, the first pixel group PG1 and the seventh pixel group PG7 may each include a first AF pixel AFPX1, a second AF pixel AFPX2, a first normal pixel NPX1, and a second normal pixel NPX2. The second to fourth pixel groups PG2 to PG4 may include third to fourteenth normal pixels NPX3 to NPX14, and the fifth, sixth, and eighth pixel groups PG5, PG6, and PG8 may include third to fourteenth normal pixels NPX3 to NPX14. However, the disclosure is not limited thereto, and the number and arrangement relationship of AF pixels and normal pixels included in each of the first to eighth pixel groups PG1 to PG8 according to one or more embodiments may be changed in various ways.

In this case, the first AF pixel AFPX1 and the second AF pixel AFPX2 may be arranged adjacent to each other in the first direction X, and the same microlens may be displaced on the photodiode of the first AF pixel AFPX1 and the photodiode of the second AF pixel AFPX2. Depending on the shape and refractive index of the microlens, the amount of charge generated in each photodiode included in each pixel may vary, and an AF function may be performed based on a pixel signal (e.g., a phase signal) corresponding to the amount of generated charge.

The first pixel group PG1 to the eighth pixel group PG8 may receive the first to eighth transmission control signals TS_1 to TS_8 through the first to eighth transmission control lines TG_1 to TG_8. For example, the first pixel group PG1 and the seventh pixel group PG7 may receive the first to fourth transmission control signals TS_1 to TS_4 through the first to fourth transmission control lines TG_1 to TG_4, and the second to sixth pixel groups PG2 to PG6 and the eighth pixel group PG8 may receive the fifth to eighth transmission control signals TS_5 to TS_8 through the fifth transmission control line to the eighth transmission control line TG_5 to TG_8.

In one or more embodiments, the same transmission control signal, that is, the third transmission control signal TS_3, may be provided to the first AF pixel AFPX1 included in the first pixel group PG1 and the first AF pixel AFPX1 included in the seventh pixel group PG2, and the same transmission control signal, that is, the fourth transmission control signal TS_4, may be provided to the second AF pixel AFPX2 included in the first pixel group PG1 and the second AF pixel AFPX2 included in the seventh pixel group PG7. In addition, in one or more embodiments, the same transmission control signal, that is, the first transmission control signal TS_1, may be provided to the first normal pixel NPX1 included in the first pixel group PG1 and the first normal pixel NPX1 included in the seventh pixel group PG7, and the same transmission control signal, that is, the second transmission control signal TS_2, may be provided to the second normal pixel NPX2 included in the first pixel group PG1 and the second normal pixel NPX2 included in the seventh pixel group PG7.

In addition, in one or more embodiments, the same transmission control signal, that is, the fifth transmission control signal TS_5, may be provided to the third normal pixel NPX3 included in the second pixel group PG2 and the eleventh normal pixel NPX11 included in the eighth pixel group PG8, and the same transmission control signal, that is, the sixth transmission control signal TS_6, may be provided to the fourth normal pixel NPX4 included in the second pixel group PG2 and the twelfth normal pixel NPX12 included in the eighth pixel group PG8. The same transmission control signal, that is, the seventh transmission control signal TS_7, may be provided to the fifth normal pixel NPX5 included in the second pixel group PG2 and the thirteenth normal pixel NPX13 included in the eighth pixel group PG8, and the same transmission control signal, that is, the eighth transmission control signal TS_8, may be provided to the sixth normal pixel NPX6 included in the second pixel group PG2 and the fourteenth normal pixel NPX14 included in the eighth pixel group PG8.

In one or more embodiments, the same transmission control signal, that is, the fifth transmission control signal TS_5, may be provided to the seventh normal pixel NPX7 included in the third pixel group PG3 and the eleventh normal pixel NPX11 included in the fourth pixel group PG4, and the same transmission control signal, that is, the sixth transmission control signal TS_6, may be provided to the eighth normal pixel NPX8 included in the third pixel group PG3 and the twelfth normal pixel NPX12 included in the fourth pixel group PG. The same transmission control signal, that is, the seventh transmission control signal TS_7, may be provided to the ninth normal pixel NPX9 included in the third pixel group PG3 and the thirteenth normal pixel NPX13 included in the fourth pixel group PG4, and the same transmission control signal, that is, the eighth transmission control signal TS_8, may be provided to the tenth normal pixel NPX10 included in the third pixel group PG3 and the fourteenth normal pixel NPX14 included in the fourth pixel group PG4.

As described above, in the pixel array according to one or more embodiments, the same transmission control signal may be provided to pixels connected to the same transmission control line. For example, the transmission control signal provided to pixels included in the fifth pixel group PG5 and the sixth pixel group PG6 may be the same as the transmission control signal provided to pixels included in the third pixel group PG3 and the fourth pixel group PG4. However, the disclosure is not limited thereto.

The first pixel group PG1 to the fourth pixel group PG4 may be respectively connected to different column output lines (e.g., different column output lines among the first to n-th column output lines CLO_0 to CLO_n-1 in FIG. 2) and may respectively output pixel signals through the different column output lines. For example, the first pixel group PG1 may be connected to an i-th column output line CLO_i (where i is an integer that is greater than or equal to 0 and less than n−1), the second pixel group PG2 may be connected to an (i+1)-th column output line CLO_i+1, the third pixel group PG3 may be connected to an (i+2)-th column output line CLO_i+2, and the fourth pixel group PG4 may be connected to an (i+3)-th column output line CLO_i+3.

In addition, the fifth to eighth pixel groups PG5 to PG8 may be respectively connected to different column output lines and may respectively output pixel signals through the different column output lines.

Because the same transmission control signal, that is, the third transmission control signal TS_3, is provided to the first AF pixel AFPX1 of the first pixel group PG1 and the first AF pixel AFPX1 of the seventh pixel group PG7 and pixel signals are output through different column output lines, the first AF pixel AFPX1 of the first pixel group PG1 and the first AF pixel AFPX1 of the seventh pixel group PG7 may simultaneously output pixel signals (e.g., phase signals) including AF information. Therefore, the image sensor according to one or more embodiments may perform an AF function at high speed based on pixels (or AF pixels) having DCC structures.

The pixel array 110a may include a color filter to sense various colors. In one or more embodiments, each of the first to eighth pixel groups PG1 to PG8 may include one of a green color filter GF, a red color filter RF, and a blue color filter BF. For example, each of the first to eighth pixel groups PG1 to PG8 may include a color filter to correspond to a Bayer pattern. For example, the first pixel group PG1, the third pixel group PG3, the fifth pixel group PG5, and the seventh pixel group PG7 may each include the green color filter GF, the second pixel group PG2, the fourth pixel group PG4, the sixth pixel group PG6, and the eighth pixel group PG8 may each include the red color filter RF, and the remaining pixel groups may each include the blue color filter BF. However, the disclosure is not limited thereto, and each of the first to eighth pixel groups PG1 to PG8 may include at least one of a white color filter, a yellow color filter, a cyan color filter, and a magenta color filter.

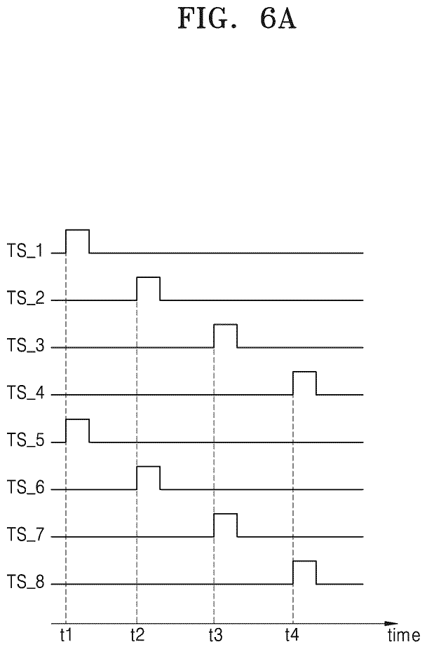

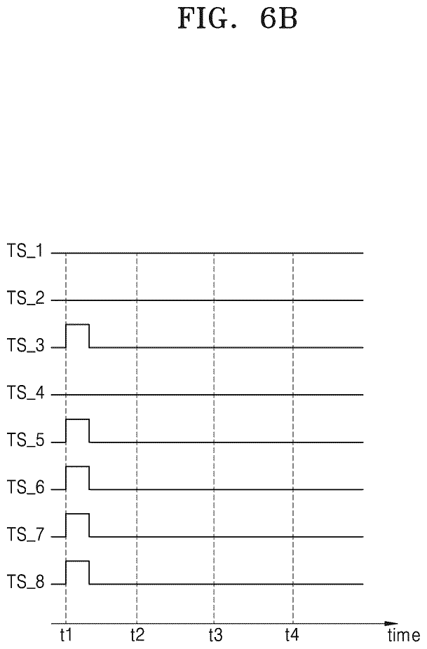

FIGS. 6A and 6B are timing diagrams illustrating transmission control signals provided to the first pixel group PG1 and the second pixel group PG2 in FIG. 5, according to one or more embodiments.

An image sensor according to one or more embodiments may operate in a first mode or a second mode based on the amount of light received through a plurality of pixels. In this case, the first mode may refer to a full mode, and the second mode may refer to a 4-SUM mode (or binning mode). FIG. 6A is a timing diagram illustrating transmission control signals when the image sensor operates in an AF operation in the first mode (i.e., the full mode). For example, in the first mode, each of the pixels included in a pixel group having an 2×2 structure may output one pixel signal, and in the second mode, all pixels included in the pixel group having the 2×2 structure may output one pixel signal.

Referring to FIGS. 5 and 6A, the image sensor according to one or more embodiments may read out a pixel signal from each pixel of the pixel array 110a according to a reset-signal (RS) readout method during an AF operation in the first mode.

Referring to FIGS. 5 and 6A, when the image sensor according to one or more embodiments operates in the AF operation, as a transmission control signal is provided from the row driver 140 to each pixel of the pixel array 110a through the first to eighth transmission control lines TG_1 to TG_8, the transmission control signal may transition from a logic low level to a logic high level.

As the first to fourth transmission control signals TS_1 to TS_4 are provided from the row driver 140 to each pixel of the pixel array 110a through the first to fourth transmission control lines TG_1 to TG_4, the first to fourth transmission control signals TS_1 to TS_4 may transition from a logic low level to a logic high level. For example, the first transmission control signal TS_1, the second transmission control signal TS_2, the third transmission control signal TS_3, and the fourth transmission control signal TS_4 may sequentially transition from a logic low level to a logic high level according to a predetermined order at first, second, third, and fourth times t1, t2, t3, and t4.

Referring to FIG. 6A, at the same time as the first to fourth transmission control signals TS_1 to TS_4 are provided from the row driver 140 to each pixel of the first pixel group PG1, the fifth to eighth transmission control signals TS_5 to TS_8 may be provided to each pixel of the pixel array 110a through the fifth transmission control line to the eighth transmission control line TG_5 to TG_8. For example, at the first time t1, the first transmission control signal TS_1 and the fifth transmission control signal TS_5 may simultaneously transition from a logic low level to a logic high level. At the second time t2, the second transmission control signal TS_2 and the sixth transmission control signal TS_6 may simultaneously transition from a logic low level to a logic high level. At the third time t3, the third transmission control signal TS_3 and the seventh transmission control signal TS_7 may simultaneously transition from a logic low level to a logic high level. At the fourth time t4, the fourth transmission control signal TS_4 and the eighth transmission control signal TS_8 may simultaneously transition from a logic low level to a logic high level.

Transfer transistors, to which the first transmission control signal TS1, the second transmission control signal TS2, the third transmission control signal TS3, the fourth transmission control signal TS4, the fifth transmission control signal TS5, the sixth transmission control signal TS6, the seventh transmission control signal TS7, and the eighth transmission control signal TS8 are respectively provided, may be sequentially turned on at the first, second, third, and fourth times t1, t2, t3, and t4, and thus, pixel signals (e.g., phase signals or color signals) corresponding to photo charges generated in photodiodes respectively connected to the transfer transistors may be generated. For example, transfer transistors to which the first transmission control signal TS_1 and the fifth transmission control signal TS_5 are respectively provided may be turned on at the first time t1, and transfer transistors to which the second transmission control signal TS_2 and the sixth transmission control signal TS_6 are respectively provided may be turned on at the second time t2. In addition, transfer transistors to which the third transmission control signal TS_3 and the seventh transmission control signal TS_7 are respectively provided may be turned on at the third time t3, and transfer transistors to which the fourth transmission control signal TS_4 and the eighth transmission control signal TS_8 are respectively provided may be turned on at the fourth time t4.

With respect to the AF operation in the first mode of the image sensor described above with reference to FIG. 5, the descriptions of transmission control signals (e.g., the first to eighth transmission control signals TS_1 to TS_8) for the first to fourth pixel groups PG1 to PG4 arranged in the N-th row and (N+1)-th row may also apply to transmission control signals (e.g., the first to eighth transmission control signals TS_1 to TS_8) for the fifth to eighth pixel groups PG5 to PG8 arranged in the (N+4)-th row and (N+5)-th row.

Accordingly, the image sensor according to one or more embodiments may generate and output phase data by using a pixel signal output from the first AF pixel AFPX1 disposed in the (N+1)-th row of the first pixel group PG1 and a pixel signal output from the first AF pixel AFPX1 disposed in the (N+5)-th row of the seventh pixel group PG7 and may perform an AF operation (i.e., an autofocus function) in the first mode based on the generated phase data. In this case, the first AF pixel AFPX1 of the first pixel group PG1 and the first AF pixel AFPX1 of the seventh pixel group PG7 may be target AF pixels. The target AF pixels may each refer to an AF pixel that outputs a pixel signal (e.g., a phase signal) including AF information in a corresponding readout cycle. For example, the first AF pixel AFPX1 of the first pixel group PG1 may generate a pixel signal including first AF information (e.g., left phase information), and the first AF pixel AFPX1 of the seventh pixel group PG7 may generate a pixel signal including second AF information (e.g., right phase information).

In addition, the image sensor according to one or more embodiments may generate and output phase data by using a pixel signal output from the second AF pixel AFPX2 disposed in the (N+1)-th row of the first pixel group PG1 and a pixel signal output from the second AF pixel AFPX2 disposed in the (N+5)-th row of the seventh pixel group PG7 and may perform an AF operation (i.e., an autofocus function) in the first mode based on the generated phase data. In this case, the second AF pixel AFPX2 of the first pixel group PG1 and the second AF pixel AFPX2 of the seventh pixel group PG7 may be target AF pixels. For example, the second AF pixel AFPX2 of the seventh pixel group PG7 may generate a pixel signal including first AF information (e.g., left phase information), and the second AF pixel AFPX2 of the first pixel group PG1 may generate a pixel signal including second AF information (e.g., right phase information).

FIG. 6B is a timing diagram illustrating transmission control signals when the image sensor operates in an AF operation in the second mode (i.e., the 4-SUM mode (or binning mode)).

Referring to FIGS. 5 and 6B, the image sensor according to one or more embodiments may read out a pixel signal from each pixel of the pixel array 110a according to an RS readout method during an AF operation in the second mode.

Referring to FIGS. 5 and 6B, when the image sensor according to one or more embodiments operates in the AF operation in the second mode, as a transmission control signal is provided from the row driver 140 to each pixel of the pixel array 110a through the first to eighth transmission control lines TG_1 to TG_8, the transmission control signal may transition from a logic low level to a logic high level.

Referring to FIG. 6B, at the same time as the third transmission control signal TS_3 is provided from the row driver 140, the fifth to eighth transmission controls TS_5 to TS_8 may be provided to each pixel of the pixel array 110a through the fifth transmission control line to the eighth transmission control line TG_5 to TG_8. For example, at the first time t1, the third transmission control signal TS_3 and the fifth to eighth transmission control signals TS_5 to TS_8 may simultaneously transition from a logic low level to a logic high level.

Transfer transistors, to which the third transmission control signal TS3, the fifth transmission control signal TS5, the sixth transmission control signal TS6, the seventh transmission control signal TS7, and the eighth transmission control signal TS8 are respectively provided, may be turned on at the first time t1, and thus, pixel signals (e.g., phase signals or color signals) corresponding to photo charges generated in corresponding photodiodes may be generated.

With respect to the AF operation in the second mode of the image sensor described above with reference to FIG. 5, the descriptions of transmission control signals (e.g., the first to eighth transmission control signals TS_1 to TS_8) for the first to fourth pixel groups PG1 to PG4 arranged in the N-th row and (N+1)-th row may also apply to transmission control signals (e.g., the first to eighth transmission control signals TS_1 to TS_8) for the fifth to eighth pixel groups PG5 to PG8 arranged in the (N+4)-th row and (N+5)-th row.

The image sensor according to one or more embodiments may generate and output phase data by using a pixel signal output from the first AF pixel AFPX1 disposed in the (N+1)-th row of the first pixel group PG1 and a pixel signal output from the first AF pixel AFPX1 disposed in the (N+5)-th row of the seventh pixel group PG7 and may perform an AF operation (i.e., an autofocus function) in the second mode based on the generated phase data. In this case, the first AF pixel AFPX1 of the first pixel group PG1 and the first AF pixel AFPX1 of the seventh pixel group PG7 may be target AF pixels. The target AF pixels may each refer to an AF pixel that outputs a pixel signal (e.g., a phase signal) including AF information in a corresponding readout cycle. For example, the first AF pixel AFPX1 of the first pixel group PG1 may generate a pixel signal including first AF information (e.g., left phase information), and the first AF pixel AFPX1 of the seventh pixel group PG7 may generate a pixel signal including second AF information (e.g., right phase information).

For convenience of explanation, with reference to FIG. 6B, the AF operation in the second mode has been described based on the first AF pixel AFPX1 of the first pixel group PG1 and the first AF pixel AFPX1 of the seventh pixel group PG7. However, the disclosure is not limited thereto, and the image sensor according to one or more embodiments may perform the AF operation in the second mode based on other AF pixels (e.g., the second AF pixel AFPX2 of the first pixel group PG1 and the second AF pixel AFPX2 of the seventh pixel group PG7) in FIG. 5. In this case, the second AF pixel AFPX2 of the seventh pixel group PG1 may generate a pixel signal including first AF information (e.g., left phase information), and the second AF pixel AFPX2 of the first pixel group PG1 may generate a pixel signal including second AF information (e.g., right phase information).

The first to eighth transmission control signals TS_1 to TS_8 illustrated in FIGS. 6A and 6B are examples, and the image sensor according to one or more embodiments is not limited thereto. Depending on the intensity of light, etc., the transition timing of each of the first to eighth transmission control signals TS_1 to TS_8 may vary. For example, when relatively dark light is incident on the image sensor, the first to eighth transmission control signals TS_1 to TS_8 illustrated in FIG. 6A may be provided to the pixel array 110a, and when relatively bright light is incident on the image sensor, the first to eighth transmission control signals TS_1 to TS_8 illustrated in FIG. 6B may be provided to the pixel array 110a.

Therefore, as described with reference to FIGS. 6A and 6B, the image sensor according to one or more embodiments may perform a high-speed AF operation by separately processing pixel signals of AF pixels based on pixels having DCC structures. Furthermore, the image sensor according to one or more embodiments may perform an AF operation in each operation mode (e.g., the first mode (i.e., the full mode) or the second mode (i.e., the 4-SUM mode)) selected according to the amount of received light.

FIG. 7 is a diagram illustrating a pixel array 110b of an image sensor according to one or more embodiments.

In FIG. 7, the pixel array 110b may include a plurality of pixel groups arranged in a plurality of rows (e.g., N-th row to (N+7)-th row) and a plurality of columns (e.g., M-th column to (M+7)-th column). The description of the pixel array 110b of FIG. 7, which is the same as the description of FIG. 5, is omitted.

Referring to FIG. 7, each of the first to eighth pixel groups PG1 to PG8 may include four pixels arranged in two rows and two columns. In one or more embodiments, the first pixel group PG1 and the seventh pixel group PG7 may each include a first AF pixel AFPX1, a second AF pixel AFPX2, a first normal pixel NPX1, and a second normal pixel NPX2. The second to fourth pixel groups PG2 to PG4 may include third to fourteenth normal pixels NPX3 to NPX14, and the fifth, sixth, and eighth pixel groups PG5, PG6, and PG8 may include third to fourteenth normal pixels NPX3 to NPX14. However, the disclosure is not limited thereto, and the number and arrangement relationship of AF pixels and normal pixels included in each of the first to eighth pixel groups PG1 to PG8 may be changed in various ways.

In this case, the first AF pixel AFPX1 and the second AF pixel AFPX2 may be arranged adjacent to each other in the first direction X, and the same microlens may be displaced on the photodiode of the first AF pixel AFPX1 and the photodiode of the second AF pixel AFPX2. Depending on the shape and refractive index of the microlens, the amount of charge generated in each photodiode included in each pixel may vary, and an AF function may be performed based on a pixel signal (e.g., a phase signal) corresponding to the amount of charge generated in the photodiode.

The first pixel group PG1 to the eighth pixel group PG8 may receive the first to fifth transmission control signals TS_1 to TS_5 through the first to fifth transmission control lines TG_1 to TG_5. For example, the first pixel group PG1 and the seventh pixel group PG7 may receive the first transmission control signal TS_1, the second transmission control signal TS_2, the fourth transmission control signal TS_4, and the fifth transmission control signal TS_5 through the first transmission control line TG_1, the second transmission control line TG_2, the fourth transmission control line TG_4, and the fifth transmission control line TG_5. The second to sixth pixel groups PG2 to PG6 and the eighth pixel group PG8 may receive the first to fourth transmission control signals TS_1 to TS_4 through the first to fourth transmission control lines TG_1 to TG_4.

In one or more embodiments, the same transmission control signal, that is, the fourth transmission control signal TS_4, may be provided to the first AF pixel AFPX1 included in the first pixel group PG1 and the first AF pixel AFPX1 included in the seventh pixel group PG2, and the same transmission control signal, that is, the fifth transmission control signal TS_5, may be provided to the second AF pixel AFPX2 included in the first pixel group PG1 and the second AF pixel AFPX2 included in the seventh pixel group PG7. In addition, in one or more embodiments, the same transmission control signal, that is, the first transmission control signal TS_1, may be provided to the first normal pixel NPX1 included in the first pixel group PG1 and the first normal pixel NPX1 included in the seventh pixel group PG7, and the same transmission control signal, that is, the second transmission control signal TS_2, may be provided to the second normal pixel NPX2 included in the first pixel group PG1 and the second normal pixel NPX2 included in the seventh pixel group PG7.

In addition, in one or more embodiments, the same transmission control signal, that is, the first transmission control signal TS_1, may be provided to the third normal pixel NPX3 included in the second pixel group PG2 and the eleventh normal pixel NPX11 included in the eighth pixel group PG8, and the same transmission control signal, that is, the second transmission control signal TS_2, may be provided to the fourth normal pixel NPX4 included in the second pixel group PG2 and the twelfth normal pixel NPX12 included in the eighth pixel group PG8. The same transmission control signal, that is, the third transmission control signal TS_3, may be provided to the fifth normal pixel NPX5 included in the second pixel group PG2 and the thirteenth normal pixel NPX13 included in the eighth pixel group PG8, and the same transmission control signal, that is, the fourth transmission control signal TS_4, may be provided to the sixth normal pixel NPX6 included in the second pixel group PG2 and the fourteenth normal pixel NPX14 included in the eighth pixel group PG8.

As described above, in the pixel array according to one or more embodiments, the same transmission control signal may be provided to pixels connected to the same transmission control line. For example, the transmission control signal provided to pixels included in the third to sixth pixel groups PG3 to PG6 may be the same as the transmission control signal provided to pixels included in the second pixel group PG2 (or the eighth pixel group PG8). However, the disclosure is not limited thereto.

The first pixel group PG1 to the fourth pixel group PG4 may be respectively connected to different column output lines (e.g., different column output lines among the first to n-th column output lines CLO_0 to CLO_n−1 in FIG. 2) and may respectively output pixel signals through the different column output lines. For example, the first pixel group PG1 may be connected to an i-th column output line CLO_i (where i is an integer that is greater than or equal to 0 and less than n−1), the second pixel group PG2 may be connected to an (i+1)-th column output line CLO_i+1, the third pixel group PG3 may be connected to an (i+2)-th column output line CLO_i+2, and the fourth pixel group PG4 may be connected to an (i+3)-th column output line CLO_i+3.

In addition, the fifth to eighth pixel groups PG5 to PG8 may be respectively connected to different column output lines and may respectively output pixel signals through the different column output lines.

Because the same transmission control signal, that is, the third transmission control signal TS_3, is provided to the first AF pixel AFPX1 of the first pixel group PG1 and the first AF pixel AFPX1 of the seventh pixel group PG7 and pixel signals are output through different column output lines, the first AF pixel AFPX1 of the first pixel group PG1 and the first AF pixel AFPX1 of the seventh pixel group PG7 may simultaneously output pixel signals (e.g., phase signals) including AF information. Therefore, the image sensor according to one or more embodiments may perform an AF function at high speed based on pixels (or AF pixels) having DCC structures.

The pixel array 110a may include a color filter to sense various colors. In one or more embodiments, each of the first to eighth pixel groups PG1 to PG8 may include one of a green color filter GF, a red color filter RF, and a blue color filter BF. For example, each of the first to eighth pixel groups PG1 to PG8 may include a color filter to correspond to a Bayer pattern. For example, the first pixel group PG1, the third pixel group PG3, the fifth pixel group PG5, and the seventh pixel group PG7 may each include the green color filter GF, the second pixel group PG2, the fourth pixel group PG4, the sixth pixel group PG6, and the eighth pixel group PG8 may each include the red color filter RF, and the remaining pixel groups may each include the blue color filter BF. However, the disclosure is not limited thereto, and each of the first to eighth pixel groups PG1 to PG8 may include at least one of a white color filter, a yellow color filter, a cyan color filter, and a magenta color filter.

Therefore, the image sensor according to one or more embodiments may secure layout margin by reducing the number of transmission control lines arranged in the pixel array 110b by changing the readout method (for example: changing from the RS readout method to a reset-signal-signal (RSS) readout method). Furthermore, embodiments of the disclosure may provide an image sensor capable of stably performing an AF operation and reducing the probability of defects occurring in the product production process through secured layout gains.

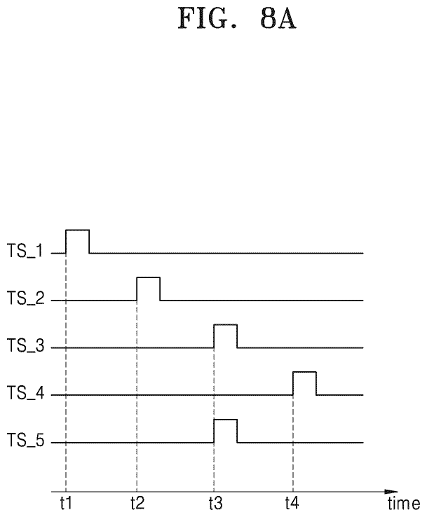

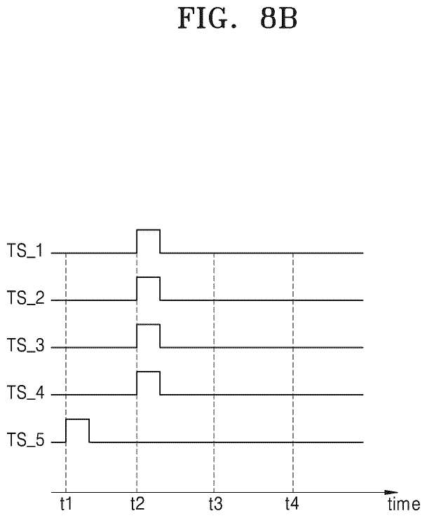

FIGS. 8A and 8B are timing diagrams illustrating transmission control signals provided to the first pixel group PG1 and the second pixel group PG2 in FIG. 7, according to one or more embodiments.

An image sensor according to one or more embodiments may operate in a first mode or a second mode based on the amount of light received through a plurality of pixels. In this case, the first mode may refer to a full mode, and the second mode may refer to a 4-SUM mode (or binning mode). FIG. 8A is a timing diagram illustrating transmission control signals when the image sensor operates in an AF operation in the first mode (i.e., the full mode). The description of FIGS. 8A and 8B, which is the same as the description of FIGS. 6A and 6B, is omitted.

Referring to FIGS. 7 and 8A, the image sensor according to one or more embodiments may read out a pixel signal from each pixel of the pixel array 110b according to a RS readout method during an AF operation in the first mode.

Referring to FIGS. 7 and 8A, when the image sensor according to one or more embodiments operates in the AF operation, as a transmission control signal is provided from the row driver 140 to each pixel of the pixel array 110b through the first to fifth transmission control lines TG_1 to TG_5, the transmission control signal may transition from a logic low level to a logic high level.

Referring to FIG. 8A, as the first to fourth transmission control signals TS_1 to TS_4 are provided from the row driver 140 to each pixel of the pixel array 110b through the first to fourth transmission control lines TG_1 to TG_4, the first to fourth transmission control signals TS_1 to TS_4 may transition from a logic low level to a logic high level. For example, the first transmission control signal TS_1, the second transmission control signal TS_2, the third transmission control signal TS_3, and the fourth transmission control signal TS_4 may sequentially transition from a logic low level to a logic high level according to a predetermined order at first, second, third, and fourth times t1, t2, t3, and t4.

Referring to FIG. 8A, the row driver 140 may provide the fifth transmission control signal TS_5 to each pixel of the pixel array 110b through the fifth transmission control line TG_5 at the same time as providing the third transmission control signal TS_3 to each pixel of the pixel array 110b. For example, at the third time t3, the third transmission control signal TS_3 and the fifth transmission control signal TS_5 may simultaneously transition from a logic low level to a logic high level.

Transfer transistors, to which the first transmission control signal TS1, the second transmission control signal TS2, the third transmission control signal TS3, the fourth transmission control signal TS4, and the fifth transmission control signal TS5 are respectively provided, may be sequentially turned on at the first, second, third, and fourth times t1, t2, t3, and t4, and thus, pixel signals (e.g., phase signals or color signals) corresponding to photo charges generated in photodiodes respectively connected to the transfer transistors may be generated. For example, transfer transistors to which the first transmission control signal TS_1 are provided may be turned on at the first time t1, and transfer transistors to which the second transmission control signal TS_2 is provided may be turned on at the second time t2. In addition, transfer transistors to which the third transmission control signal TS_3 and the fifth transmission control signal TS_5 are respectively provided may be turned on at the third time t3, and transfer transistors to which the fourth transmission control signal TS_4 are provided may be turned on at the fourth time t4.

With respect to the AF operation in the first mode of the image sensor described above with reference to FIG. 7, the descriptions of transmission control signals (e.g., the first to eighth transmission control signals TS_1 to TS_8) for the first to fourth pixel groups PG1 to PG4 arranged in the N-th row and (N+1)-th row may also apply to transmission control signals (e.g., the first to eighth transmission control signals TS_1 to TS_8) for the fifth to eighth pixel groups PG5 to PG8 arranged in the (N+4)-th row and (N+5)-th row.

The image sensor according to one or more embodiments may generate and output phase data by using a pixel signal output from the second AF pixel AFPX2 disposed in the (N+1)-th row of the first pixel group PG1 and a pixel signal output from the second AF pixel AFPX2 disposed in the (N+5)-th row of the seventh pixel group PG7 and may perform an AF operation (i.e., an autofocus function) in the first mode based on the generated phase data. In this case, the second AF pixel AFPX2 of the seventh pixel group PG1 may generate a pixel signal including first AF information (e.g., left phase information), and the second AF pixel AFPX2 of the first pixel group PG1 may generate a pixel signal including second AF information (e.g., right phase information).

For convenience of explanation, with reference to FIG. 8A, an AF operation based on the second AF pixel AFPX2 of the first pixel group PG1 and the second AF pixel AFPX2 of the seventh pixel group PG7 has been described. However, the disclosure is not limited thereto. For example, the image sensor according to one or more embodiments may perform the AF operation in the first mode based on other AF pixels (e.g., the first AF pixel AFPX1 of the first pixel group PG1 and the first AF pixel AFPX1 of the seventh pixel group PG7) in FIG. 7. The first AF pixel AFPX1 of the first pixel group PG1 may generate a pixel signal including first AF information (e.g., left phase information), and the first AF pixel AFPX1 of the seventh pixel group PG7 may generate a pixel signal including second AF information (e.g., right phase information).

FIG. 8B is a timing diagram illustrating transmission control signals when the image sensor operates in an AF operation in the second mode (i.e., the 4-SUM mode (or binning mode)).

Referring to FIGS. 7 and 8B, the image sensor according to one or more embodiments may read out a pixel signal from each pixel of the pixel array 110b according to an RSS readout method during an AF operation in the second mode.

Referring to FIGS. 7 and 8B, when the image sensor according to one or more embodiments operates in the AF operation in the second mode, as a transmission control signal is provided from the row driver 140 to each pixel of the pixel array 110b through the first to fifth transmission control lines TG_1 to TG_5, the transmission control signal may transition from a logic low level to a logic high level.

Referring to FIG. 8B, a fifth transmission control signal TS_5 may be provided from the row driver 140. For example, at the first time t1, which is a first readout time of the RSS readout method, the fifth transmission control signal TS_5 may transition from a logic low level to a logic high level.

Referring to FIG. 8B, after the first time t1, first to fourth transmission control signals TS_1 to TS_4 may be provided from the row driver 140 to each pixel of the pixel array 110b through the first to fourth transmission control lines TG_1 to TG_4. For example, at the second time t2, which is a second readout time of the RSS readout method, the first to fourth transmission control signals TS_1 to TS_4 may simultaneously transition from a logic low level to a logic high level.

Transfer transistors, to which the fifth transfer control signal TS5 are provided, may be turned on at the first time t1, and thus, pixel signals (e.g., phase signals) corresponding to photo charge generated in a photodiode connected to the transfer transistors may be generated.

Transfer transistors, to which the first transmission control signal TS1, the second transmission control signal TS2, the third transmission control signal TS3, and the fourth transmission control signal TS4 are respectively provided, may be turned on at the second time t2, and thus, pixel signals (e.g., color signals) corresponding to photo charges generated in corresponding photodiodes may be generated.

With respect to the AF operation in the second mode of the image sensor described above with reference to FIG. 5, the descriptions of transmission control signals (e.g., the first to fifth transmission control signals TS_1 to TS_5) for the first to fourth pixel groups PG1 to PG4 arranged in the N-th row and (N+1)-th row may also apply to transmission control signals (e.g., the first to fifth transmission control signals TS_1 to TS_5) for the fifth to eighth pixel groups PG5 to PG8 arranged in the (N+4)-th row and (N+5)-th row.

The image sensor according to one or more embodiments may generate and output phase data by using a pixel signal output from the second AF pixel AFPX2 disposed in the (N+1)-th row of the first pixel group PG1 and a pixel signal output from the second AF pixel AFPX2 disposed in the (N+5)-th row of the seventh pixel group PG7 and may perform an AF operation (i.e., an autofocus function) in the second mode based on the generated phase data. In this case, the second AF pixel AFPX2 of the seventh pixel group PG1 may generate a pixel signal including first AF information (e.g., left phase information), and the second AF pixel AFPX2 of the first pixel group PG1 may generate a pixel signal including second AF information (e.g., right phase information).

For convenience of explanation, with reference to FIG. 8B, an AF operation based on the second AF pixel AFPX2 of the first pixel group PG1 and the second AF pixel AFPX2 of the seventh pixel group PG7 has been described. However, the disclosure is not limited thereto. For example, the image sensor according to one or more embodiments may perform the AF operation in the second mode based on other AF pixels (e.g., the first AF pixel AFPX1 of the first pixel group PG1 and the first AF pixel AFPX1 of the seventh pixel group PG7) in FIG. 7. In this case, the first AF pixel AFPX1 of the first pixel group PG1 may generate a pixel signal including first AF information (e.g., left phase information), and the first AF pixel AFPX1 of the seventh pixel group PG7 may generate a pixel signal including second AF information (e.g., right phase information).

The first to fifth transmission control signals TS_1 to TS_5 illustrated in FIGS. 8A and 8B are examples, and the image sensor according to one or more embodiments is not limited thereto. Depending on the intensity of light, etc., the transition timing of each of the first to fifth transmission control signals TS_1 to TS_5 may vary. For example, when relatively dark light is incident on the image sensor, the first to fifth transmission control signals TS_1 to TS_5 illustrated in FIG. 8A may be provided to the pixel array 110b, and when relatively bright light is incident on the image sensor, the first to fifth transmission control signals TS_1 to TS_5 illustrated in FIG. 8B may be provided to the pixel array 110b.

Therefore, as described with reference to FIGS. 8A and 8B, the image sensor according to one or more embodiments may perform a high-speed AF operation based on pixels having DCC structures. Furthermore, the image sensor according to one or more embodiments may perform an AF operation in each operation mode (e.g., the first mode (i.e., the full mode) or the second mode (i.e., the 4-SUM mode)) selected according to the amount of received light.

In addition, the image sensor according to one or more embodiments may secure a layout gain by reducing the number of transmission control lines in a pixel array through a change in the readout method (e.g., changing to the RSS readout method).

FIG. 9 is a diagram illustrating a pixel array 110c of an image sensor according to one or more embodiments.

In FIG. 9, the pixel array 110b may include a plurality of pixel groups arranged in a plurality of rows (e.g., N-th row to (N+7)-th row) and a plurality of columns (e.g., M-th column to (M+7)-th column). The description of the pixel array 110c of FIG. 9, which is the same as the description of FIGS. 5 and 7, is omitted.

Referring to FIG. 9, each of the first to eighth pixel groups PG1 to PG8 may include four pixels arranged in two rows and two columns. In one or more embodiments, the first pixel group PG1 and the seventh pixel group PG7 may each include a first AF pixel AFPX1, a second AF pixel AFPX2, a third AF pixel AFPX3, and a fourth AF pixel AFPX4. The second to fourth pixel groups PG2 to PG4 may include third to fourteenth normal pixels NPX3 to NPX14, and the fifth, sixth, and eighth pixel groups PG5, PG6, and PG8 may include third to fourteenth normal pixels NPX3 to NPX14. However, the disclosure is not limited thereto, and the number and arrangement relationship of AF pixels and normal pixels included in each of the first to eighth pixel groups PG1 to PG8 may be changed in various ways.

In this case, the first AF pixel AFPX1 and the second AF pixel AFPX2 may be arranged adjacent to each other in the first direction X, and the same microlens (e.g., a first microlens) may be displaced on the photodiode of the first AF pixel AFPX1 and the photodiode of the second AF pixel AFPX2. In addition, the third AF pixel AFPX3 and the fourth AF pixel AFPX4 may be arranged adjacent to each other in the first direction X, and the same microlens (e.g., a second microlens) may be displaced on the photodiode of the third AF pixel AFPX3 and the photodiode of the fourth AF pixel AFPX4. Depending on the shape and refractive index of the microlens, the amount of charge generated in each photodiode included in each pixel may vary, and an AF function may be performed based on a pixel signal (e.g., a phase signal) corresponding to the amount of charge generated in the photodiode.

The first pixel group PG1 to the eighth pixel group PG8 may receive the first to sixth transmission control signals TS_1 to TS_6 through the first to sixth transmission control lines TG_1 to TG_6. For example, the first pixel group PG1 and the seventh pixel group PG7 may receive the fourth transmission control signal TS_4 and the fifth transmission control signal TS_5 through the fourth transmission control line TG_4 and the fifth transmission control line TG_5. The second to sixth pixel groups PG2 to PG6 and the eighth pixel group PG8 may receive the first to fourth transmission control signals TS_1 to TS_4 through the first to fourth transmission control lines TG_1 to TG_4.

In one or more embodiments, the same transmission control signal, that is, the first transmission control signal TS_1, may be provided to the first AF pixel AFPX1 included in the first pixel group PG1 and the first AF pixel AFPX1 included in the seventh pixel group PG2, and the same transmission control signal, that is, the fifth transmission control signal TS_5, may be provided to the second AF pixel AFPX2 included in the first pixel group PG1 and the second AF pixel AFPX2 included in the seventh pixel group PG7. In addition, in one or more embodiments, the same transmission control signal, that is, the third transmission control signal TS_3, may be provided to the third AF pixel AFPX3 included in the first pixel group PG1 and the third AF pixel AFPX3 included in the seventh pixel group PG7, and the same transmission control signal, that is, the sixth transmission control signal TS_6, may be provided to the fourth AF pixel AFPX4 included in the first pixel group PG1 and the fourth AF pixel AFPX4 included in the seventh pixel group PG7.

In addition, in one or more embodiments, the same transmission control signal, that is, the first transmission control signal TS_1, may be provided to the third normal pixel NPX3 included in the second pixel group PG2 and the eleventh normal pixel NPX11 included in the eighth pixel group PG8, and the same transmission control signal, that is, the second transmission control signal TS_2, may be provided to the fourth normal pixel NPX4 included in the second pixel group PG2 and the twelfth normal pixel NPX12 included in the eighth pixel group PG8. The same transmission control signal, that is, the third transmission control signal TS_3, may be provided to the fifth normal pixel NPX5 included in the second pixel group PG2 and the thirteenth normal pixel NPX13 included in the eighth pixel group PG8, and the same transmission control signal, that is, the fourth transmission control signal TS_4, may be provided to the sixth normal pixel NPX6 included in the second pixel group PG2 and the fourteenth normal pixel NPX14 included in the eighth pixel group PG8.

As described above, in the pixel array according to one or more embodiments, the same transmission control signal may be provided to pixels connected to the same transmission control line. For example, the transmission control signal provided to pixels included in the third to sixth pixel groups PG3 to PG6 may be the same as the transmission control signal provided to pixels included in the second pixel group PG2 (or the eighth pixel group PG8). However, the disclosure is not limited thereto.

The first pixel group PG1 to the fourth pixel group PG4 may be respectively connected to different column output lines (e.g., different column output lines among the first to n-th column output lines CLO_0 to CLO_n−1 in FIG. 2) and may respectively output pixel signals through the different column output lines. For example, the first pixel group PG1 may be connected to an i-th column output line CLO_i (where i is an integer that is greater than or equal to 0 and less than n−1), the second pixel group PG2 may be connected to an (i+1)-th column output line CLO_i+1, the third pixel group PG3 may be connected to an (i+2)-th column output line CLO_i+2, and the fourth pixel group PG4 may be connected to an (i+3)-th column output line CLO_i+3.

In addition, the fifth to eighth pixel groups PG5 to PG8 may be respectively connected to different column output lines and may respectively output pixel signals through the different column output lines.

Because the same transmission control signal, that is, the first transmission control signal TS_1, is provided to the first AF pixel AFPX1 of the first pixel group PG1 and the first AF pixel AFPX1 of the seventh pixel group PG7 and pixel signals are output through different column output lines, the first AF pixel AFPX1 of the first pixel group PG1 and the first AF pixel AFPX1 of the seventh pixel group PG7 may simultaneously output pixel signals (e.g., phase signals) including AF information. Therefore, the image sensor according to one or more embodiments may perform an AF function at high speed based on pixels (or AF pixels) having DCC structures.

The pixel array 110c may include a color filter to sense various colors. In one or more embodiments, each of the first to eighth pixel groups PG1 to PG8 may include one of a green color filter GF, a red color filter RF, and a blue color filter BF. For example, each of the first to eighth pixel groups PG1 to PG8 may include a color filter to correspond to a Bayer pattern. For example, the first pixel group PG1, the third pixel group PG3, the fifth pixel group PG5, and the seventh pixel group PG7 may each include the green color filter GF, the second pixel group PG2, the fourth pixel group PG4, the sixth pixel group PG6, and the eighth pixel group PG8 may each include the red color filter RF, and the remaining pixel groups may each include the blue color filter BF. However, the disclosure is not limited thereto, and each of the first to eighth pixel groups PG1 to PG8 may include at least one of a white color filter, a yellow color filter, a cyan color filter, and a magenta color filter.

Accordingly, the image sensor according to one or more embodiments may improve the accuracy of focus control during an AF operation as the number of AF pixels included in one pixel group increases.

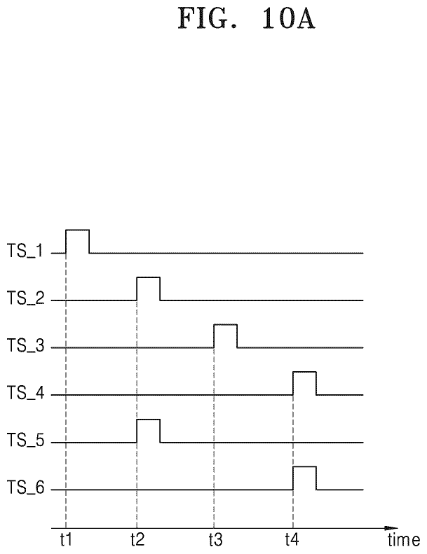

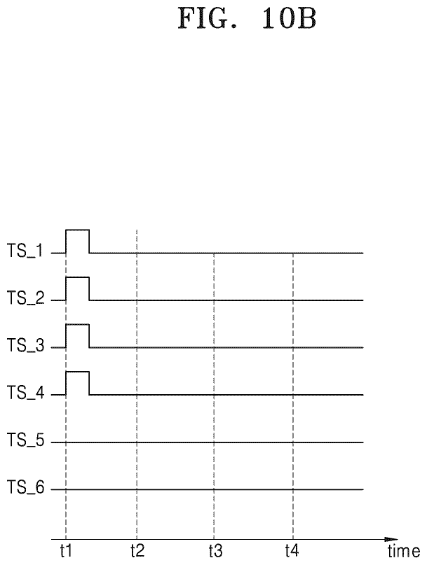

FIGS. 10A and 10B are timing diagrams illustrating transmission control signals provided to the first pixel group PG1 and the second pixel group PG2 in FIG. 9, according to one or more embodiments.

An image sensor according to one or more embodiments may operate in a first mode or a second mode based on the amount of light received through a plurality of pixels. In this case, the first mode may refer to a full mode, and the second mode may refer to a 4-SUM mode (or binning mode). FIG. 10A is a timing diagram illustrating transmission control signals when the image sensor operates in an AF operation in the first mode (i.e., the full mode). The description of FIGS. 10A and 10B, which is the same as the description of FIGS. 6A and 6B or FIGS. 8A and 8B, is omitted.

Referring to FIGS. 9 and 10A, the image sensor according to one or more embodiments may read out a pixel signal from each pixel of the pixel array 110c according to a RS readout method during an AF operation in the first mode.

Referring to FIGS. 9 and 10A, when the image sensor according to one or more embodiments operates in the AF operation, as a transmission control signal is provided from the row driver 140 to each pixel of the pixel array 110c through the first to sixth transmission control lines TG_1 to TG_6, the transmission control signal may transition from a logic low level to a logic high level.

Referring to FIG. 10A, as the first to sixth transmission control signals TS_1 to TS_6 are provided from the row driver 140 to each pixel of the pixel array 110c through the first to sixth transmission control lines TG_1 to TG_6, the first to sixth transmission control signals TS_1 to TS_6 may transition from a logic low level to a logic high level. For example, the first transmission control signal TS_1, the second transmission control signal TS_2, the third transmission control signal TS_3, and the fourth transmission control signal TS_4 may sequentially transition from a logic low level to a logic high level according to a predetermined order at first, second, third, and fourth times t1, t2, t3, and t4.

Referring to FIG. 10A, at the same time as the first to fourth transmission control signals TS_1 to TS_4 are provided from the row driver 140 to each pixel of the first pixel group PG1, the fifth and sixth transmission control signals TS_5 and TS_6 may be provided to each pixel of the pixel array 110c through the fifth and sixth transmission control lines TG_5 and TG_6. For example, at the first time t1, the first transmission control signal TS_1 may transition from a logic low level to a logic high level. At the second time t2, the second transmission control signal TS_2 and the fifth transmission control signal TS_5 may simultaneously transition from a logic low level to a logic high level. At the third time t3, the third transmission control signal TS_3 may transition from a logic low level to a logic high level. At the fourth time t4, the fourth transmission control signal TS_4 and the sixth transmission control signal TS_6 may simultaneously transition from a logic low level to a logic high level.

Transfer transistors, to which the first transmission control signal TS1, the second transmission control signal TS2, the third transmission control signal TS3, the fourth transmission control signal TS4, the fifth transmission control signal TS5, and the sixth transmission control signal TS6 are respectively provided, may be sequentially turned on at the first, second, third, and fourth times t1, t2, t3, and t4, and thus, pixel signals (e.g., phase signals or color signals) corresponding to photo charges generated in photodiodes respectively connected to the transfer transistors may be generated. For example, transfer transistors to which the first transmission control signal TS_1 are provided may be turned on at the first time t1, and transfer transistors to which the second transmission control signal TS_2 and the fifth transmission control signal TS_5 are respectively provided may be turned on at the second time t2. In addition, transfer transistors to which the third transmission control signal TS_3 are provided may be turned on at the third time t3, and transfer transistors to which the fourth transmission control signal TS_4 and the sixth transmission control signal TS_6 are respectively provided may be turned on at the fourth time t4.

With respect to the AF operation in the first mode of the image sensor described above with reference to FIG. 9, the descriptions of transmission control signals (e.g., the first to sixth transmission control signals TS_1 to TS_6) for the first to fourth pixel groups PG1 to PG4 arranged in the N-th row and (N+1)-th row may also apply to transmission control signals (e.g., the first to sixth transmission control signals TS_1 to TS_6) for the fifth to eighth pixel groups PG5 to PG8 arranged in the (N+4)-th row and (N+5)-th row.

Therefore, the image sensor according to one or more embodiments may generate and output phase data, at the second time t2, by using a pixel signal output from the second AF pixel AFPX2 disposed in the N-th row of the first pixel group PG1 and a pixel signal output from the second AF pixel AFPX2 disposed in the (N+4)-th row of the seventh pixel group PG7 and may perform an AF operation (i.e., an autofocus function) in the first mode based on the generated phase data. In this case, the second AF pixel AFPX2 of the seventh pixel group PG1 may generate a pixel signal including first AF information (e.g., left phase information), and the second AF pixel AFPX2 of the first pixel group PG1 may generate a pixel signal including second AF information (e.g., right phase information). In addition, the image sensor according to one or more embodiments may generate and output phase data, at the fourth time t4, by using a pixel signal output from the fourth AF pixel AFPX4 disposed in the (N+1)-th row of the first pixel group PG1 and a pixel signal output from the fourth AF pixel AFPX4 disposed in the (N+5)-th row of the seventh pixel group PG7 and may perform an AF operation (i.e., an autofocus function) in the first mode based on the generated phase data. In this case, the fourth AF pixel AFPX4 of the seventh pixel group PG1 may generate a pixel signal including first AF information (e.g., left phase information), and the fourth AF pixel AFPX4 of the first pixel group PG1 may generate a pixel signal including second AF information (e.g., right phase information).

For convenience of explanation, with reference to FIG. 10A, an AF operation based on the second and fourth AF pixels AFPX2 and AFPX4 of the first pixel group PG1 and the second and fourth AF pixels AFPX2 and AFPX4 of the seventh pixel group PG7 has been described. However, the disclosure is not limited thereto. For example, the image sensor according to one or more embodiments may perform the AF operation in the first mode based on other AF pixels (e.g., the first and third AF pixels AFPX1 and AFPX3 of the first pixel group PG1 and the first and third AF pixels AFPX1 and AFPX3 of the seventh pixel group PG7) in FIG. 9. In this case, the first and third AF pixels AFPX1 and AFPX3 of the first pixel group PG1 may generate a pixel signal including first AF information (e.g., left phase information), and the first and third AF pixels AFPX1 and AFPX3 of the seventh pixel group PG7 may generate a pixel signal including second AF information (e.g., right phase information).

FIG. 10B is a timing diagram illustrating transmission control signals when the image sensor operates in an AF operation in the second mode (i.e., the 4-SUM mode (or binning mode)).

Referring to FIGS. 9 and 10B, the image sensor according to one or more embodiments may read out a pixel signal from each pixel of the pixel array 110c according to an RS readout method during an AF operation in the second mode.

Referring to FIGS. 9 and 10B, when the image sensor according to one or more embodiments operates in the AF operation in the second mode, as a transmission control signal is provided from the row driver 140 to each pixel of the pixel array 110c through the first to sixth transmission control lines TG_1 to TG_6, the transmission control signal may transition from a logic low level to a logic high level.

Referring to FIG. 10B, first to fourth transmission control signals TS_1 to TS_4 may be provided from the row driver 140 to each pixel of the pixel array 110c through the first to fourth transmission control lines TG_1 to TG_4. For example, at the first time t1, the first to fourth transmission control signals TS_1 to TS_4 may simultaneously transition from a logic low level to a logic high level.

Transfer transistors, to which the first transmission control signal TS1, the second transmission control signal TS2, the third transmission control signal TS3, and the fourth transmission control signal TS4 are respectively provided, may be turned on at the first time t1, and thus, pixel signals (e.g., phase signals or color signals) corresponding to photo charges generated in photodiodes respectively connected to the transfer transistors may be generated.

With respect to the AF operation in the second mode of the image sensor described above with reference to FIG. 9, the descriptions of transmission control signals (e.g., the first to fourth transmission control signals TS_1 to TS_4) for the first to fourth pixel groups PG1 to PG4 arranged in the N-th row and (N+1)-th row may also apply to transmission control signals (e.g., the first to fourth transmission control signals TS_1 to TS_4) for the fifth to eighth pixel groups PG5 to PG8 arranged in the (N+4)-th row and (N+5)-th row.

The image sensor according to one or more embodiments may generate and output phase data by using a pixel signal output from the first AF pixel AFPX1 disposed in the N-th row of the first pixel group PG1 and a pixel signal output from the third AF pixel AFPX3 disposed in the (N+1)-th row of the first pixel group PG1. In addition, the image sensor may generate and output phase data by using a pixel signal output from the first AF pixel AFPX1 disposed in the (N+4)-th row of the seventh pixel group PG7 and a pixel signal output from the third AF pixel AFPX3 disposed in the (N+5)-th row of the seventh pixel group PG7. In this case, the first AF pixel AFPX1 and the third AF pixel AFPX3 of the first pixel group PG1 may generate a pixel signal including first AF information (e.g., left phase information), and the first AF pixel AFPX1 and the third AF pixel AFPX3 of the seventh pixel group PG7 may generate a pixel signal including second AF information (e.g., right phase information). The image sensor may perform an AF operation in the second mode based on the generated phase data.

Therefore, as described with reference to FIG. 10B, the image sensor according to one or more embodiments may improve the accuracy of the AF operation of the image sensor by generating left phase information based on a plurality of AF pixels (e.g., the first and third AF pixels AFPX1 and AFPX3 of the first pixel group PG1) and generating right phase information based on a plurality of other AF pixels (e.g., the first and third AF pixels AFPX1 and AFPX3 of the seventh pixel group PG7.

For convenience of explanation, with reference to FIG. 10B, an AF operation based on the first and third AF pixels AFPX1 and AFPX3 of the first pixel group PG1 and the first and third AF pixels AFPX1 and AFPX3 of the seventh pixel group PG7 has been described. However, the disclosure is not limited thereto. For example, the image sensor according to one or more embodiments may perform the AF operation in the first mode based on other AF pixels (e.g., the second and fourth AF pixels AFPX2 and AFPX4 of the first pixel group PG1 and the second and fourth AF pixels AFPX2 and AFPX4 of the seventh pixel group PG7) in FIG. 9. In this case, the second and fourth AF pixels AFPX2 and AFPX4 of the seventh pixel group PG7 may generate a pixel signal including first AF information (e.g., left phase information), and the second and fourth AF pixels AFPX2 and AFPX4 of the first pixel group PG1 may generate a pixel signal including second AF information (e.g., right phase information).

As described with reference to FIGS. 10A and 10B, the image sensor according to one or more embodiments may select an operation mode (e.g., a first mode or a second mode) according to the amount of received light and may adaptively perform an AF operation according to the selected operation mode.

The first to sixth transmission control signals TS_1 to TS_6 illustrated in FIGS. 10A and 10B are examples, and the image sensor according to one or more embodiments is not limited thereto. Depending on the intensity of light, etc., the transition timing of each of the first to sixth transmission control signals TS_1 to TS_6 may vary. For example, when relatively dark light is incident on the image sensor, the first to sixth transmission control signals TS_1 to TS_6 illustrated in FIG. 10A may be provided to the pixel array 110c, and when relatively bright light is incident on the image sensor, the first to sixth transmission control signals TS_1 to TS_6 illustrated in FIG. 10B may be provided to the pixel array 110c.

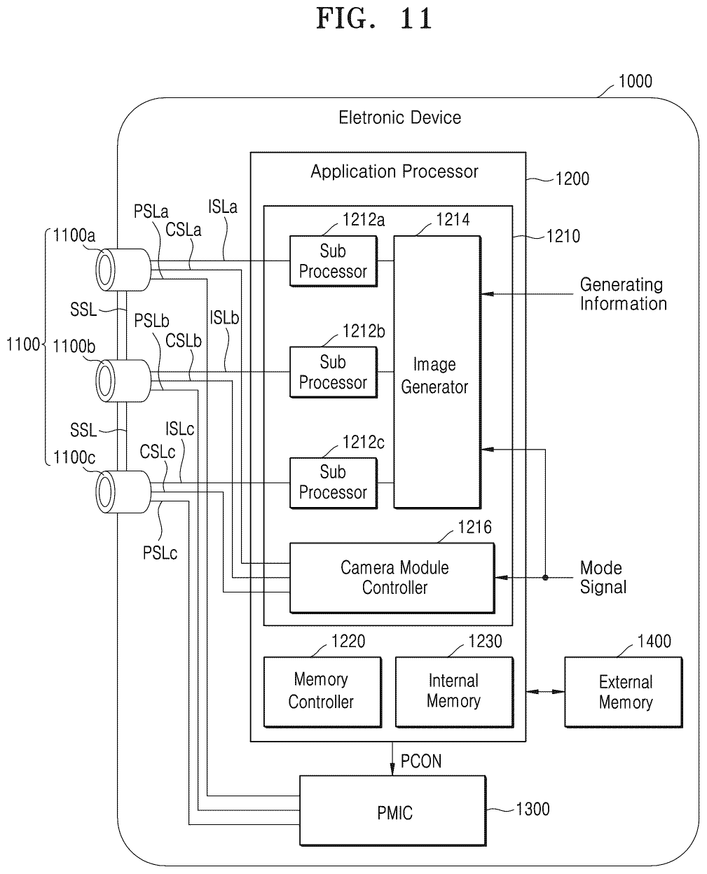

FIG. 11 is a block diagram of an electronic device 1000 including a multi-camera module according to one or more embodiments.

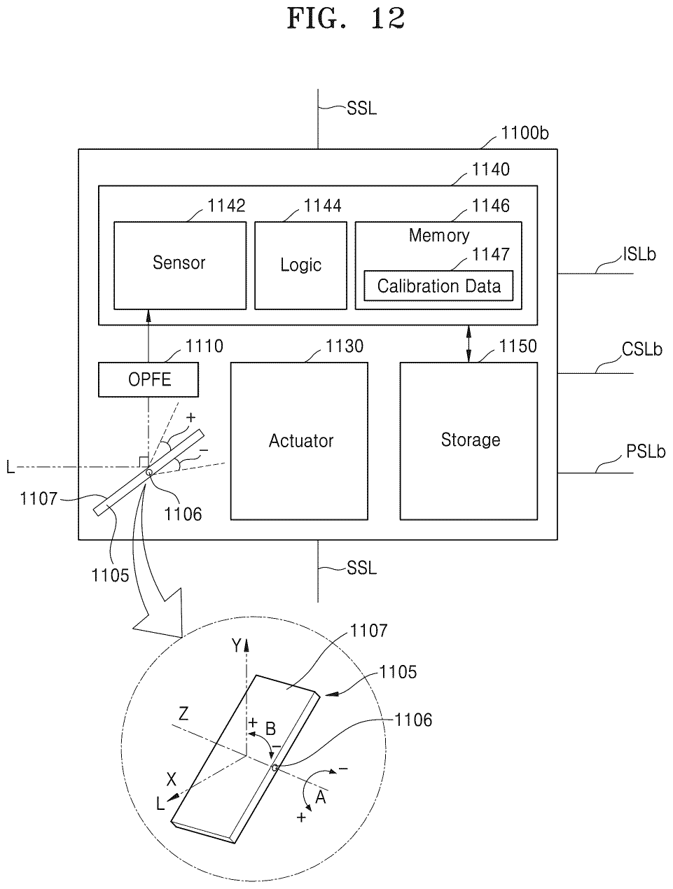

FIG. 12 is a detailed block diagram of the camera module of FIG. 11 according to one or more embodiments. Although FIG. 12 shows the detailed configuration of a camera module 1100b, the following description may equally apply to other camera modules 1100a and 1100c depending on one or more embodiments.

Referring to FIG. 11, the electronic device 1000 may include a camera module group 1100, an application processor 1200, a power module integrated circuit (PMIC) 1300, and external memory 1400. The camera module group 1100 may include a plurality of camera modules 1100a, 1100b, and 1100c. Although it is illustrated in FIG. 10 that the three camera modules 1100a, 1100b, and 1100c are arranged, embodiments are not limited thereto.

Referring to FIGS. 11 and 12, the camera module 1100b may include a prism 1105, an optical path folding element (OPFE) 1110, an actuator 1130, an image sensing device 1140, and a storage 1150.

The prism 1105 may include a reflective surface 1107 of a light reflective material to change a path of light L incident from the outside. The OPFE 1110 may include, for example, optical lenses consisting of m (m is a natural number) groups. The actuator 1130 may move the OPFE 1110 or an optical lens to a certain position.

The image sensing device 1140 may include an image sensor 1142, a control logic 1144, and a memory 1146. The image sensor 1142 may sense an image to be sensed by using the light L provided through the optical lens. The image sensor 1142 may be the image sensor 100 described with reference to FIG. 1 and may include at least one of the pixel arrays 110a to 110c described with reference to FIGS. 5, 7, and 9.

The control logic 1144 may control all operations of the camera module 1100b. For example, the control logic 1144 may control the operation of the camera module 1100b according to a control signal provided through a control signal line CSLb.

In one or more embodiments, one of the plurality of camera modules 1100a, 1100b, and 1100c (for example, 1100b) may include a camera module in the form of a folded lens including the prism 1105 and the OPFE 1110 described above, and the remaining camera modules (for example, 1100a and 1100b) may include vertical camera modules that do not include the prism 1105 and the OPFE 1110. However, embodiments are not limited thereto.

In one or more embodiments, one of the plurality of camera modules 1100a, 1100b, and 1100c (for example, 1100c) may include, for example, a vertical depth camera extracting depth information by using infrared ray (IR). In this case, the application processor 1200 may merge an image data value provided by the depth camera with an image data value provided by another camera module (for example, 1100a or 1100b) to generate a 3D depth image.

In one or more embodiments, at least two camera modules (for example, 1100a and 1100b) among the plurality of camera modules 1100a, 1100b, and 1100c may have different fields of view. In this case, for example, the at least two camera modules (for example, 1100a and 1100b) among the plurality of camera modules 1100a, 1100b, and 1100c may have different optical lenses. However, the disclosure is not limited thereto.

In addition, in one or more embodiments, the plurality of camera modules 1100a, 1100b, and 1100c may have different fields of view. In this case, the plurality of camera modules 1100a, 1100b, and 1100c may have different optical lenses. However, the disclosure is not limited thereto.

In one or more embodiments, the plurality of camera modules 1100a, 1100b, and 1100c may be physically separated from one another. That is, a sensing region of the image sensor 1142 is not divided and used by the plurality of camera modules 1100a, 1100b, and 1100c, but an independent image sensor 1142 may be arranged in each of the plurality of camera modules 1100a, 1100b, and 1100c.

Referring back to FIG. 11, the application processor 1200 may include an image processing device 1210, a memory controller 1220, and internal memory 1230. The application processor 1200 may be implemented separately from the plurality of camera modules 1100a, 1100b, and 1100c. For example, the application processor 1200 and the plurality of camera modules 1100a, 1100b, and 1100c may be implemented separately from one another as separate semiconductor chips.

The image processing device 1210 may include a plurality of sub-image processors 1212a, 1212b, and 1212c, an image generator 1214, and a camera module controller 1216.

The image processing device 1210 may include the plurality of sub-image processors 1212a, 1212b, and 1212c of which number corresponds to the number of camera modules 1100a, 1100b, and 1100c.

Image data values generated by the camera modules 1100a, 1100b, and 1100c, respectively, may be provided to the corresponding sub-image processors 1212a, 1212b, and 1212c through image signal lines ISLa, ISLb, and ISLc separated from one another. For example, the image data value generated by the camera module 1100a may be provided to the sub-image processor 1212a through the image signal line ISLa, the image data value generated by the camera module 1100b may be provided to the sub-image processor 1212b through the image signal line ISLb, and the image data value generated by the camera module 1100c may be provided to the sub-image processor 1212c through the image signal line ISLc. Transmission of such image data values may be performed by using, for example, a camera serial interface (CSI) based on a mobile industry processor interface (MIPI). However, embodiments are not limited thereto.

The image data value provided to each of the sub-image processors 1212a, 1212b, and 1212c may be provided to the image generator 1214. The image generator 1214 may generate an output image by using the image data provided by each of the sub-image processors 1212a, 1212b, and 1212c according to image generation formation or a mode signal.

Specifically, the image generator 1214 may merge at least some of the image data values generated by the camera modules 1100a, 1100b, and 1100c having different fields of view with one another according to the image generation information or the mode signal to generate the output image. In addition, the image generator 1214 may select one of the image data values generated by the camera modules 1100a, 1100b, and 1100c having different fields of view with one another according to the image generation information or the mode signal to generate the output image.

The camera module controller 1216 may provide control signals to the camera modules 1100a, 1100b, and 1100c. The control signals generated by the camera module controller 1216 may be provided to the corresponding camera modules 1100a, 1100b, and 1100c through separate control signal lines CSLa, CSLb, and CSLc, respectively.

The application processor 1200 may store the received image data values, that is, the encoded data, in the internal memory 1230 in the application processor 1200 or the external memory 1400 outside the application processor 1200, may read out the encoded data from the internal memory 1230 or the external memory 1400, and may display an image generated based on the decoded image data value. For example, a corresponding sub-processor among the plurality of sub-image processors 1212a, 1212b, and 1212c of the image processing device 1210 may perform decoding, and may also perform image processing on the decoded image data value.

The PMIC 1300 may supply power, for example, a power voltage, to each of the plurality of camera modules 1100a, 1100b, and 1100c. For example, under control of the application processor 1200, the PMIC 1300 may supply first power to the camera module 1100a through a power signal line PSLa, may supply second power to the camera module 1100b through a power signal line PSLb, and may supply third power to the camera module 1100c through a power signal line PSLc.

While the disclosure has been particularly shown and described with reference to embodiments thereof, it will be understood that various changes in form and details may be made therein without departing from the spirit and scope of the following claims.

What is claimed is:

1. An image sensor comprising:
a pixel array comprising:
a first pixel group comprising first pixels, wherein the first pixels comprising:
a first auto-focus (AF) pixel;
a second AF pixel;
a first normal pixel; and
a second normal pixel; and
a second pixel group comprising second pixels, wherein the second pixels comprising:
a third normal pixel;
a fourth normal pixel;
a fifth normal pixel; and
a sixth normal pixel;
a row driver configured to provide a transmission control signal to the pixel array through transmission control lines, the transmission control lines comprising a first transmission control line, a second transmission control line, a third transmission control line, a fourth transmission control line, a fifth transmission control line, a sixth transmission control line, a seventh transmission control line, and an eighth transmission control line; and
a readout circuit electrically connected to the first pixels and the second pixels,
wherein the first pixels are connected to the row driver through any one of the first transmission control line, the second transmission control line, the third transmission control line, and the fourth transmission control line, and
wherein the second pixels are connected to the row driver through the fifth transmission control line, the sixth transmission control line, the seventh transmission control line, and the eighth transmission control line.

2. The image sensor of claim 1, further comprising:
a first floating diffusion node positioned at a center of the first pixel group and electrically connected to the first pixels;
a second floating diffusion node positioned at a center of the second pixel group and electrically connected to the second pixels; and
a device isolation pattern that electrically separates the first pixel group from the second pixel group, wherein the device isolation pattern comprises:
parts disposed between and electrically separating the first pixels and disposed between and electrically separating the second pixels,
wherein the parts are spaced apart from the first floating diffusion node and the second floating diffusion node.

3. The image sensor of claim 1,
wherein the image sensor is configured to operate in a first mode or a second mode based on an amount of light received through the first pixels and the second pixels, and
wherein the row driver is further configured to, in the first mode:
provide the transmission control signal to the first pixels through the first transmission control line, the second transmission control line, the third transmission control line, and the fourth transmission control line in a predetermined order; and
provide the transmission control signal to the second pixels through the fifth transmission control line, the sixth transmission control line, the seventh transmission control line, and the eighth transmission control line at a same time as providing the transmission control signal through the first transmission control line, the second transmission control line, the third transmission control line, and the fourth transmission control line.

4. The image sensor of claim 3, further comprising:
an image signal processor,
wherein, in the first mode, the readout circuit is configured to:
output phase data based on a phase signal received from a target AF pixel in the first pixel group; and
output image data based on color signals received from the first normal pixel and the second normal pixel and the second pixels,
wherein the image signal processor is configured to perform an AF operation based on the phase data, and
wherein the target AF pixel is either the first AF pixel or the second AF pixel.

5. The image sensor of claim 3, wherein the row driver is further configured to, in the second mode:
provide the transmission control signal to the third normal pixel, the fourth normal pixel, the fifth normal pixel, and the sixth normal pixel through the fifth transmission control line, the sixth transmission control line, the seventh transmission control line, and the eighth transmission control line at a same time as providing the transmission control signal to a target AF pixel through a transmission control line corresponding to the target AF pixel from among the first transmission control line, the second transmission control line, the third transmission control line, and the fourth transmission control line,
wherein the target AF pixel is either the first AF pixel or the second AF pixel.

6. The image sensor of claim 5, further comprising:
an image signal processor,
wherein the readout circuit is configured to, in the second mode, output phase data based on a phase signal received from the target AF pixel in the first pixel group and output image data based on color signals received from the second pixels, and
wherein the image signal processor is configured to perform an AF operation based on the phase data.

7. The image sensor of claim 1, wherein the first AF pixel and the second AF pixel are disposed adjacent to each other in a horizontal direction.

8. An image sensor comprising:
a pixel array comprising:
a first pixel group comprising first pixels, wherein the first pixels comprising:
a first auto-focus (AF) pixel;
a second AF pixel;
a first normal pixel; and
a second normal pixel, and
a second pixel group comprising second pixels, wherein the second pixels comprising:
a third normal pixel;
a fourth normal pixel;
a fifth normal pixel; and
a sixth normal pixel;
a row driver configured to provide a transmission control signal to the pixel array through transmission control lines, the transmission control lines comprising a first transmission control line, a second transmission control line, a third transmission control line, a fourth transmission control line, and a fifth transmission control line; and
a readout circuit electrically connected to the first pixels and the second pixels,
wherein remaining pixels excluding a target AF pixel among the first pixels and the second pixels are connected to the row driver through any one of the first transmission control line, the second transmission control line, the third transmission control line, and the fourth transmission control line, and
wherein the target AF pixel is either the first AF pixel or the second AF pixel and is connected to the row driver through the fifth transmission control line.

9. The image sensor of claim 8, wherein the first normal pixel and the third normal pixel are connected to the first transmission control line,
wherein the second normal pixel and the fourth normal pixel are connected to the second transmission control line,
wherein the fifth normal pixel is connected to the third transmission control line, and
wherein the first AF pixel and the sixth normal pixel are connected to the fourth transmission control line.

10. The image sensor of claim 8, further comprising:
a first floating diffusion node positioned at a center of the first pixel group and electrically connected to the first pixels;
a second floating diffusion node positioned at a center of the second pixel group and electrically connected to the second pixels; and
a device isolation pattern that electrically separates the first pixel group from the second pixel group, wherein the device isolation pattern comprises parts disposed between and electrically separating the first pixels and disposed between and electrically separating the second pixels,
wherein the parts are spaced apart from the first floating diffusion node and the second floating diffusion node.

11. The image sensor of claim 8, wherein the image sensor is configured to operate in a first mode or a second mode based on an amount of light received through the first pixels and the second pixels, and
wherein the row driver is further configured to, in the first mode:
provide the transmission control signal to the first pixels and the second pixels through the first transmission control line, the second transmission control line, the third transmission control line, and the fourth transmission control line in a predetermined order; and
provide the transmission control signal to the target AF pixel in the first pixel group through the fifth transmission control line at a same time as providing the transmission control signal through any one of the first transmission control line, the second transmission control line, the third transmission control line, and the fourth transmission control line.

12. The image sensor of claim 11, further comprising:
an image signal processor,
wherein, in the first mode, the readout circuit is configured to:
output phase data based on a phase signal received from the target AF pixel; and
output image data based on color signals received from the remaining pixels, and
wherein the image signal processor is configured to perform an AF function based on the phase data.

13. The image sensor of claim 11, wherein, in the second mode, the row driver is further configured to:
provide the transmission control signal to the target AF pixel through the fifth transmission control line; and
provide the transmission control signal to the second pixels through the first transmission control line, the second transmission control line, the third transmission control line, and the fourth transmission control line after providing the transmission control signal to the target AF pixel.

14. The image sensor of claim 13, further comprising:
an image signal processor,
wherein the readout circuit is configured to, in the second mode, output phase data based on a phase signal received from the target AF pixel and output image data based on a color signal received from one of the second pixels, and
wherein the image signal processor is configured to, in the second mode, perform an AF operation based on the phase data.

15. The image sensor of claim 8, wherein the first AF pixel and the second AF pixel are adjacent to each other in a horizontal direction.

16. The image sensor of claim 14, wherein the readout circuit is configured to read out pixel signals from the first pixels and the second pixels according to a reset-signal-signal (RSS) readout method in the second mode.

17. An image sensor comprising:
a pixel array comprising:
a first pixel group comprising first pixels, wherein the first pixels comprising:
a first auto-focus (AF) pixel;
a second AF pixel;
a third AF pixel; and
a fourth AF pixel; and
a second pixel group comprising second pixels, wherein the second pixels comprising:
a first normal pixel;
a second normal pixel;
a third normal pixel; and
a fourth normal pixel;
a row driver configured to provide a transmission control signal to the pixel array through transmission control lines, the transmission control lines comprising a first transmission control line, a second transmission control line, a third transmission control line, a fourth transmission control line, a fifth transmission control line, and a sixth transmission control line; and
a readout circuit electrically connected to the first pixels and the second pixels,
wherein the first AF pixel and the first normal pixel are connected to the first transmission control line,
wherein the second normal pixel is connected to the second transmission control line,
wherein the third AF pixel and the third normal pixel of are connected to the third transmission control line,
wherein the fourth normal pixel is connected to the fourth transmission control line,
wherein the second AF pixel is connected to the row driver through the fifth transmission control line, and
wherein the fourth AF pixel is connected to the row driver through the sixth transmission control line.

18. The image sensor of claim 17, further comprising:
a first floating diffusion node positioned at a center of the first pixel group and electrically connected to the first pixels;
a second floating diffusion node positioned at a center of the second pixel group and electrically connected to the second pixels; and
a device isolation pattern that electrically separates the first pixel group from the second pixel group, wherein the device isolation pattern comprises parts disposed between and electrically separating the first pixels and disposed between and electrically separating the second pixels,
wherein the parts are spaced apart from the first floating diffusion node and the second floating diffusion node,
wherein the first AF pixel and the second AF pixel are adjacent to each other in a horizontal direction, and
wherein the third AF pixel and the fourth AF pixel are adjacent to each other in the horizontal direction.

19. The image sensor of claim 17, further comprising:
an image signal processor,
wherein the image sensor is configured to operate in a first mode or a second mode based on an amount of light received through the first pixels and the second pixels, and
wherein the row driver is further configured to, in the first mode:
provide the transmission control signal to the first pixels and the second pixels through the first transmission control line, the second transmission control line, the third transmission control line, and the fourth transmission control line in a predetermined order;
provide the transmission control signal to the second AF pixel through the fifth transmission control line at a same time as providing the transmission control signal through the second transmission control line; and
provide the transmission control signal to the fourth AF pixel through the sixth transmission control line at a same time as providing the transmission control signal through the fourth transmission control line,
wherein the readout circuit is configured to, in the first mode:
output phase data based on phase signals received from the first AF pixel, the second AF pixel, the third AF pixel, and the fourth AF pixel; and
output image data based on color signals received from the first normal pixel, the second normal pixel, the third normal pixel, and the fourth normal pixel, and
wherein the image signal processor is configured to, in the first mode, perform an AF operation based on the phase data.

20. The image sensor of claim 19, wherein the row driver is further configured to, in the second mode, provide the transmission control signal to the second pixels through the second transmission control line and the fourth transmission control line at a same time as providing the transmission control signal to the first AF pixel and the third AF pixel through the first transmission control line and the third transmission control line,
wherein the readout circuit is further configured to, in the second mode:
output the phase data based on phase signals received from the first AF pixel and the third AF pixel; and
output image data based on color signals received from the first normal pixel, the second normal pixel, the third normal pixel, and the fourth normal pixel, and
wherein the image signal processor is further configured to, in the second mode, perform the AF operation based on the phase data.
